(19) United States
(12) Patent Application Publication
(10) Pub. No.: US 2014/0027699 A1
(43) Pub. Date: Jan. 30, 2014

(54) NONVOLATILE MEMORY DEVICE

(71) Applicant: KABUSHIKI KAISHA TOSHIBA, Tokyo (JP)

(72) Inventors: Shinya AOKI, Mie-ken (JP); Katsuyuki Naito, Tokyo (JP)

(73) Assignee: KABUSHIKI KAISHA TOSHIBA, Tokyo (JP)

(21) Appl. No.: 13/949,435

(22) Filed: Jul. 24, 2013

(30) Foreign Application Priority Data
Jul. 27, 2012 (JP) 2012-167710

(51) Int. Cl. H01L 51/05

(52) U.S. Cl. CPC H01L 51/0591
USPC 257/2

(57) ABSTRACT

A nonvolatile memory device includes a first conductive unit, a second conductive unit, and a storage layer. The storage layer is provided between the first conductive unit and the second conductive unit. The storage layer includes a polyimide film and a plurality of micro particles dispersed in the polyimide film. The polyimide film includes a first polyimide made using a first source material including at least a first aromatic diamine molecule and a first aromatic tetracarboxylic dianhydride molecule. The micro particles include at least one selected from a metal atom, a metal ion, a second polyimide, a third polyimide, a first organic molecule, a second organic molecule, and an inorganic compound.

### CROSS-REFERENCE TO RELATED APPLICATIONS

This application is based upon and claims the benefit of priority from Japanese Patent Application No. 2012-167710, filed on Jul. 27, 2012; the entire contents of which are incorporated herein by reference.

### FIELD

Embodiments described herein relate generally to a nonvolatile memory device.

### BACKGROUND

The demand for nonvolatile memory devices that are small and have large bit densities is rapidly increasing. Nonvolatile memory devices that surpass the limits of existing silicon nonvolatile memory devices are being developed. For example, such a nonvolatile memory device has been proposed in which a resistance change material has a low resistance state and a high resistance state. It is desirable to increase the uniformity of the memory characteristics and increase the bit density of such a resistance change nonvolatile memory device.

### BRIEF DESCRIPTION OF THE DRAWINGS

FIG. 1 is a schematic cross-sectional view showing a nonvolatile memory device according to a first embodiment;

FIG. 2 is a partially-enlarged view showing a portion of the nonvolatile memory device according to the first embodiment;

FIG. 3A to FIG. 3D are band diagrams showing characteristics of the nonvolatile memory device according to the first embodiment;

FIG. 4A and FIG. 4B are schematic views showing other characteristics of the nonvolatile memory device according to the first embodiment;

FIG. 5A and FIG. 5B are band diagrams showing characteristics of the nonvolatile memory device according to the first embodiment;

FIG. 6 shows chemical formulas of some materials of the nonvolatile memory device according to the first embodiment;

FIG. 7 shows chemical formulas of some materials of the nonvolatile memory device according to the first embodiment;

FIG. 8A and FIG. 8B are schematic cross-sectional views showing other nonvolatile memory devices according to the first embodiment;

FIG. 9A and FIG. 9B are schematic cross-sectional views showing other nonvolatile memory devices according to the first embodiment;

FIG. 10 is a schematic perspective view showing the nonvolatile memory device according to the second embodiment;

FIG. 11 is a schematic perspective view showing another nonvolatile memory device according to the second embodiment;

FIG. 12 is a schematic view showing the nonvolatile memory device according to the second embodiment; and

FIG. 13 is a schematic cross-sectional view showing a portion of the nonvolatile memory device according to the second embodiment.

### DETAILED DESCRIPTION

According to one embodiment, a nonvolatile memory device includes a first conductive unit, a second conductive unit, and a storage layer. The storage layer is provided between the first conductive unit and the second conductive unit. The storage layer is reversibly transitionable between a first state and a second state by at least one selected from a voltage applied via the first conductive unit and the second conductive unit and a current supplied via the first conductive unit and the second conductive unit. The second state has a higher resistance than the first state. The storage layer includes a polyimide film and a plurality of micro particles dispersed in the polyimide film. The polyimide film includes a first polyimide made using a first source material including at least a first aromatic diamine molecule and a first aromatic tetracarboxylic dianhydride molecule. The micro particles include at least one selected from a metal atom, a metal ion, a second polyimide, a third polyimide, a first organic molecule, a second organic molecule, and an inorganic compound. The second polyimide is made using a second source material including at least a second aromatic diamine molecule and a second aromatic tetracarboxylic dianhydride molecule different from the first aromatic tetracarboxylic dianhydride molecule. An electron affinity of the second polyimide is greater than an electron affinity of the first polyimide. The third polyimide is made using a third source material including at least a third aromatic tetracarboxylic dianhydride molecule and a third aromatic diamine molecule different from the first aromatic diamine molecule. An ionization potential of the third polyimide is less than an ionization potential of the first polyimide. The first organic molecule is an acceptor. A molecular size of the first organic molecule is less than 1 nm. An electron affinity of the first organic molecule is greater than the electron affinity of the first polyimide. The second organic molecule is a donor. A molecular size of the second organic molecule is less than 1 nm. An ionization potential of the second organic molecule is less than the ionization potential of the first polyimide. The inorganic compound is an acceptor. A compound size of the inorganic compound is less than 1 nm.

According to another embodiment, a nonvolatile memory device includes a first conductive unit, a second conductive unit, and a storage layer. The storage layer is provided between the first conductive unit and the second conductive unit. The storage layer is reversibly transitionable between a first state and a second state by at least one selected from a voltage applied via the first conductive unit and the second conductive unit and a current supplied via the first conductive unit and the second conductive unit. The second state has a higher resistance than the first state. The storage layer includes a polyimide film made using a source material including a first aromatic diamine molecule and a first aromatic tetracarboxylic dianhydride molecule. The source material further includes at least one selected from a second aromatic tetracarboxylic dianhydride molecule and a second aromatic diamine molecule. The second aromatic tetracarboxylic dianhydride molecule is different from the first aromatic tetracarboxylic dianhydride molecule. The second aromatic diamine molecule is different from the first aromatic diamine molecule.

Various embodiments will be described hereinafter with reference to the accompanying drawings.

The drawings are schematic or conceptual; and the relationships between the thicknesses and widths of portions, the proportions of sizes between portions, etc., are not necessarily the same as the actual values thereof. Further, the dimensions and/or the proportions may be illustrated differently between the drawings, even for identical portions.

In the drawings and the specification of the application, components similar to those described in regard to a drawing thereinabove are marked with like reference numerals, and a detailed description is omitted as appropriate.

### First Embodiment

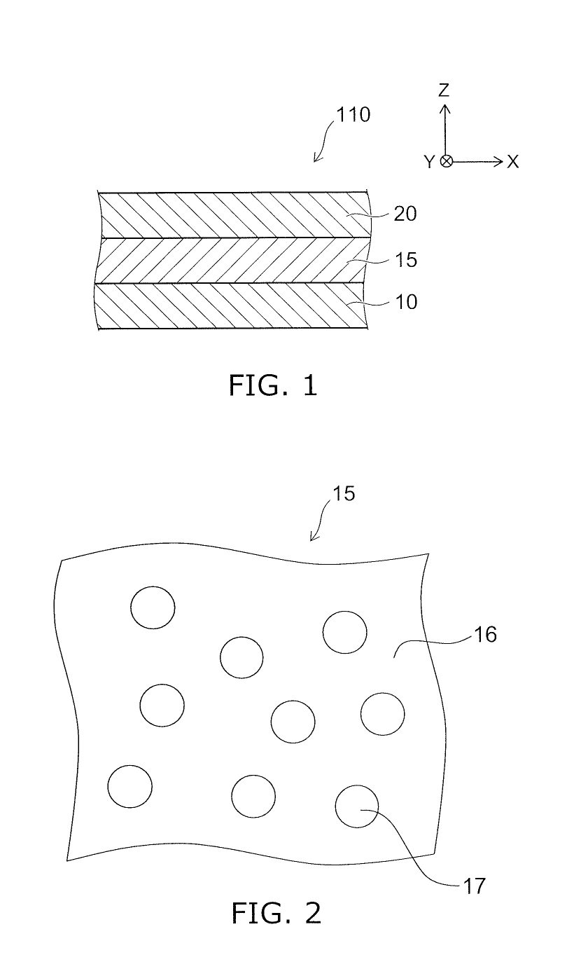

FIG. 1 is a schematic cross-sectional view showing a nonvolatile memory device according to a first embodiment.

FIG. 2 is a partially-enlarged view showing a portion of the nonvolatile memory device according to the first embodiment.

As shown in FIG. 1, the nonvolatile memory device 110 according to the embodiment includes a first conductive unit 10, a second conductive unit 20, and a storage layer 15. The storage layer 15 is provided between the first conductive unit 10 and the second conductive unit 20.

For example, a voltage may be applied to the storage layer 15 via the first conductive unit 10 and the second conductive unit 20. For example, a current may be supplied to the storage layer 15 via the first conductive unit 10 and the second conductive unit 20. The storage layer 15 is reversibly transitionable between a first state (a low resistance state) in which the resistance is low and a second state (a high resistance state) having a higher resistance than the first state by at least one selected from the voltage and the current.

The nonvolatile memory device 110 stores information by transitioning between the states of the storage layer 15. For example, the high resistance state is taken as the digital signal of “0;” and the low resistance state is taken as the digital signal of “1.” Thereby, one bit of information of the digital signal can be stored.

Herein, the stacking direction from the first conductive unit 10 toward the second conductive unit 20 is taken as a Z-axis direction. One direction perpendicular to the Z-axis direction is taken as an X-axis direction. A direction perpendicular to the Z-axis direction and the X-axis direction is taken as a Y-axis direction. In the example, the surface area of the storage layer 15 overlapping the first conductive unit 10 and the second conductive unit 20 when projected onto a plane (the X-Y plane) orthogonal to the Z-axis direction is, for example, not less than 10² nm² and not more than 10⁵ nm². In other words, the surface area of the storage layer 15 is the surface area of the memory cell of the nonvolatile memory device 110.

As shown in FIG. 2, the storage layer 15 includes a polyimide film 16 and multiple micro particles 17. For example, the multiple micro particles 17 are dispersed in the polyimide film 16.

The polyimide film 16 may include, for example, a first polyimide made using a first source material including at least a first aromatic diamine molecule and a first aromatic tetracarboxylic dianhydride molecule.

The micro particles 17 may include, for example, at least one material selected from (a) to (f) recited below.

(a) Unclustered metal atoms or unclustered metal ions

(b) A second polyimide made using a second source material including at least a second aromatic diamine molecule and a second aromatic tetracarboxylic dianhydride molecule that is different from the first aromatic tetracarboxylic dianhydride molecule

(c) A third polyimide made using a third source material including at least a third aromatic tetracarboxylic dianhydride molecule and a third aromatic diamine molecule that is different from the first aromatic diamine molecule

(d) An acceptor first organic molecule having a molecular size less than 1 nm

(e) A donor second organic molecule having a molecular size less than 1 nm

(f) An acceptor inorganic compound having a compound size less than 1 nm

In the materials recited above, the electron affinity of the second polyimide is greater than the electron affinity of the first polyimide. The ionization potential (the ionization energy) of the third polyimide is less than the ionization potential of the first polyimide. The electron affinity of the first organic molecule is greater than the electron affinity of the first polyimide. The ionization potential of the second organic molecule is less than the ionization potential of the first polyimide. The electron affinity of the inorganic compound is greater than the electron affinity of the first polyimide.

The size of the micro particle 17 is, for example, less than 1 nm. For example, the micro particle 17 is smaller than the monomer of the first polyimide. Herein, the size of the micro particle 17 is, for example, the width of the micro particle 17. In the case where the micro particle 17 has a spherical configuration, the size of the micro particle 17 is the diameter of the micro particle 17. When the size of the micro particle 17 is less than 1 nm, for example, the maximum width (the maximum diameter) of the micro particle 17 is less than 1 nm.

In the second polyimide, the second aromatic diamine molecule may be substantially the same as the first aromatic diamine molecule. In the third polyimide, the third aromatic tetracarboxylic dianhydride molecule may be substantially the same as the first aromatic tetracarboxylic dianhydride molecule.

In the case where the micro particle 17 includes the metal atom, the number of the metal atoms included inside the polyimide film 16 is, for example, not less than 10⁻⁴ per monomer unit of the first polyimide and not more than 1 per monomer unit of the first polyimide, and more favorably not less than 10⁻³ per monomer unit of the first polyimide and not more than 1 per monomer unit of the first polyimide.

In the case where the micro particle 17 includes the metal ion, the number of the metal ions included inside the polyimide film 16 is, for example, not less than 10⁻⁴ per monomer unit of the first polyimide and not more than 1 per monomer unit of the first polyimide, and more favorably not less than 10⁻³ per monomer unit of the first polyimide and not more than 1 per monomer unit of the first polyimide.

In the case where the micro particle 17 includes the second polyimide, the number of monomers of the second polyimide included inside the polyimide film 16 is, for example, not less than 10⁻⁴ per monomer unit of the first polyimide and not more than 1 per monomer unit of the first polyimide, and more favorably not less than 10⁻³ per monomer unit of the first polyimide and not more than 1 per monomer unit of the first polyimide.

In the case where the micro particle 17 includes the third polyimide, the number of monomers of the third polyimide included inside the polyimide film 16 is, for example, not less than 10⁻⁴ per monomer unit of the first polyimide and not more than 1 per monomer unit of the first polyimide, and more favorably not less than 10⁻³ per monomer unit of the first polyimide and not more than 1 per monomer unit of the first polyimide.

In the case where the micro particle 17 includes the first organic molecule, the number of the first organic molecules included inside the polyimide film 16 is, for example, not less than 10⁻⁴ per monomer unit of the first polyimide and not more than 1 per monomer unit of the first polyimide, and more favorably not less than 10⁻³ per monomer unit of the first polyimide and not more than 1 per monomer unit of the first polyimide.

In the case where the micro particle 17 includes the second organic molecule, the number of the second organic molecules included inside the polyimide film 16 is, for example, not less than 10⁻⁴ per monomer unit of the first polyimide and not more than 1 per monomer unit of the first polyimide, and more favorably not less than 10⁻³ per monomer unit of the first polyimide and not more than 1 per monomer unit of the first polyimide.

In the case where the micro particle 17 includes the inorganic compound, the number of particles of the inorganic compound included inside the polyimide film 16 is, for example, not less than 10⁻⁴ per monomer unit of the first polyimide and not more than 1 per monomer unit of the first polyimide, and more favorably not less than 10⁻³ per monomer unit of the first polyimide and not more than 1 per monomer unit of the first polyimide.

The metal atom, the metal ion, the second polyimide, the first organic molecule, and the inorganic compound are acceptor micro particles 17. The third polyimide and the second organic molecule are donor micro particles 17. The acceptor micro particles 17 function as, for example, electron traps in the bandgap (the energy region between the HOMO (Highest Occupied Molecular Orbital) and the LUMO (Lowest Unoccupied Molecular Orbital)) of the polyimide film 16 of the storage layer 15. The donor micro particles 17 function as, for example, hole traps in the bandgap of the polyimide film 16 of the storage layer 15. In the nonvolatile memory device 110, the trap and release of the charge by the micro particles 17 contributes to the expression of memory-like properties.

Hereinbelow, the state of the storage layer 15 in which electrons or holes are trapped at the micro particles 17 is called the trapped state; and the state of the storage layer 15 in which electrons or holes are not trapped at the micro particles 17 is called the untrapped state. More specifically, the trapped state is the state in which the multiple micro particles 17 included in the storage layer 15 have trapped at least a prescribed number of electrons. The untrapped state is the state in which the number of electrons trapped in the multiple micro particles 17 is less than the prescribed number.

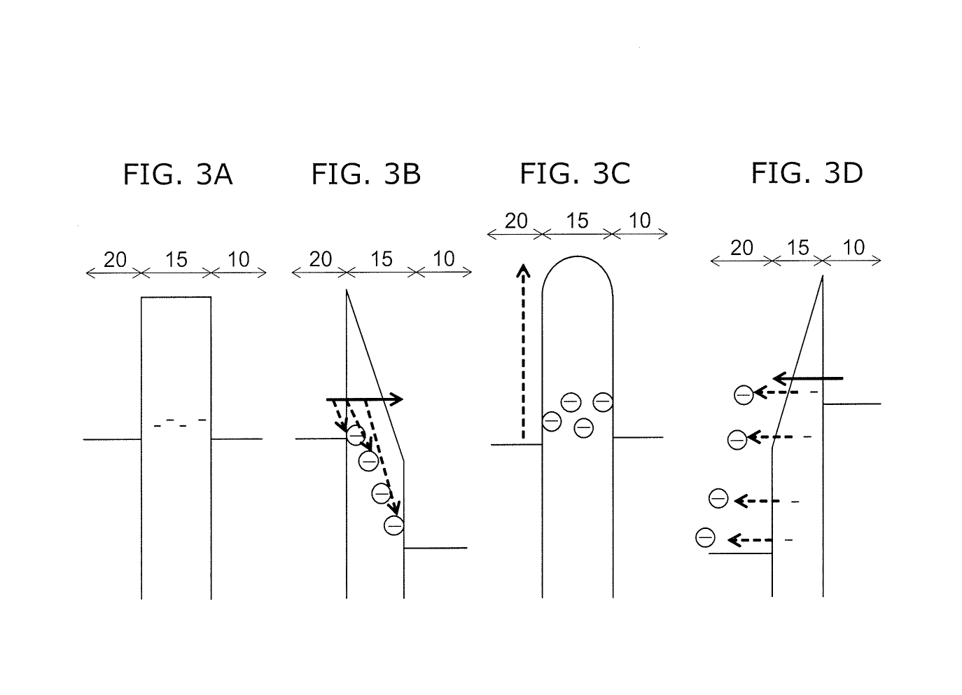

FIG. 3A to FIG. 3D are band diagrams showing characteristics of the nonvolatile memory device according to the first embodiment.

FIG. 3A to FIG. 3D show the relationship between the energy levels and the thickness-direction position from the first conductive unit 10 toward the second conductive unit 20 of the nonvolatile memory device 110 that uses acceptor micro particles 17.

The case is described where the carriers that are injected from the second conductive unit 20 or the first conductive unit 10 into the storage layer 15 are electrons; and the traps due to the micro particles 17 are electron traps. In such a case, as described below, the storage layer 15 is switched to the high resistance state (the off-state of memory) when negatively charged in the trapped state and is switched to the low resistance state (the on-state of memory) when neutral in the untrapped state.

FIG. 3A shows the state in which the storage layer 15 is in the untrapped state and a voltage is not applied between the first conductive unit 10 and the second conductive unit 20.

FIG. 3B shows the state in which a voltage is applied such that the potential of the first conductive unit 10 is higher than the potential of the second conductive unit 20. For example, the state is shown in which a negative voltage is applied to the second conductive unit 20 in the case where the first conductive unit 10 is grounded.

FIG. 3C shows the state in which the storage layer 15 is in the trapped state and a voltage is not applied between the second conductive unit 20 and the first conductive unit 10.

FIG. 3D shows the state in which a voltage is applied such that the potential of the first conductive unit 10 is lower than the potential of the second conductive unit 20. For example, the state is shown in which a positive voltage is applied to the second conductive unit 20 in the case where the first conductive unit 10 is grounded.

By applying the voltage to the storage layer 15 in the untrapped state (FIG. 3A), electrons are injected from the second conductive unit 20 into the storage layer 15 (FIG. 3B). Thereby, a portion of the electrons that are injected is trapped at the micro particles 17. In other words, the storage layer 15 transitions to the trapped state. Thereby, the micro particles 17 of the storage layer 15 are negatively charged (a negatively-charged trap level is formed). Here, in the case where the difference between the work function of the second conductive unit 20 and the LUMO level of the storage layer 15 is large, the electrons are injected from the second conductive unit 20 into the storage layer 15 by tunneling. In the case where the difference between the work function of the second conductive unit 20 and the LUMO level of the storage layer 15 is small, the electrons are injected from the second conductive unit 20 into the storage layer 15 by thermal excitation.

The micro particles 17 continue to trap the electrons even after the voltage is removed. Therefore, in the trapped state, the difference between the LUMO level of the storage layer 15 and the level of the second conductive unit 20 becomes greater than that in the untrapped state due to the Coulomb force arising from the negatively charged micro particles 17 (FIG. 3C). In other words, the barrier height increases as viewed from the level of the second conductive unit 20. As a result, the electron injection from the second conductive unit 20 into the storage layer 15 and the electronic conduction inside the storage layer 15 are suppressed. The electron injection and the electronic conduction recited above are similarly suppressed in the case of tunneling and in the case of thermal excitation. In other words, the current no longer flows easily through the storage layer 15.

Thus, in the nonvolatile memory device 110, the untrapped state is the low resistance state; and the trapped state is the high resistance state. In the nonvolatile memory device 110, one bit of information can be discriminated by, for example, measuring the state of the resistance of the storage layer 15 when applying a voltage of a forward bias that is lower than in the case where the electrons are injected into the storage layer 15.

The electrons that were trapped by the micro particles 17 can be released by applying a voltage that is reversely oriented with respect to that of FIG. 3B to the storage layer 15 (FIG. 3D). Thereby, the storage layer 15 returns from the high resistance state (the trapped state) to the low resistance state (the untrapped state).

To simplify the description recited above, the case is described where the electronic conduction inside the storage layer 15 is uniform in the film plane inside the storage layer 15. For example, a filament-like electronic conduction occurs in the case where a filament configuration that is conductive is formed due to slight dielectric breakdown inside the storage layer 15 and a portion of the filament remains as the polyimide film 16 that is insulative. Even in such a case, the LUMO level of the storage layer 15 changes because the polyimide film 16 and the micro particles 17 around the polyimide film 16 trap and release electrons; and memory-like properties can be expressed. Such conductive filaments can be formed by, for example, applying a relatively large voltage to the film at the initial stages of depositing the storage layer 15 (forming).

It is favorable for the density of the negatively charged micro particles 17 inside the storage layer 15 to be greater than 10¹⁸ cm⁻³. Thereby, the difference between the LUMO level of the storage layer 15 and the level of the second conductive unit 20 can be significantly greater than that in the untrapped state due to the Coulomb force arising from the negatively charged micro particles 17 in the case where, for example, the electronic conduction inside the storage layer 15 is uniform in the film plane inside the storage layer 15, the distribution of the micro particles 17 inside the storage layer 15 is, for example, uniform, and the thickness of the storage layer 15 is, for example, about 20 nm. The density of the monomer unit of the first polyimide included in the storage layer 15 is not less than about 10²¹ cm⁻³ and not more than about 3×10²¹ cm⁻³. Accordingly, it is favorable for the number of the micro particles 17 to be not less than 10⁻⁴ per monomer unit of the first polyimide, and more favorably not less than 10⁻³ per monomer unit of the first polyimide.

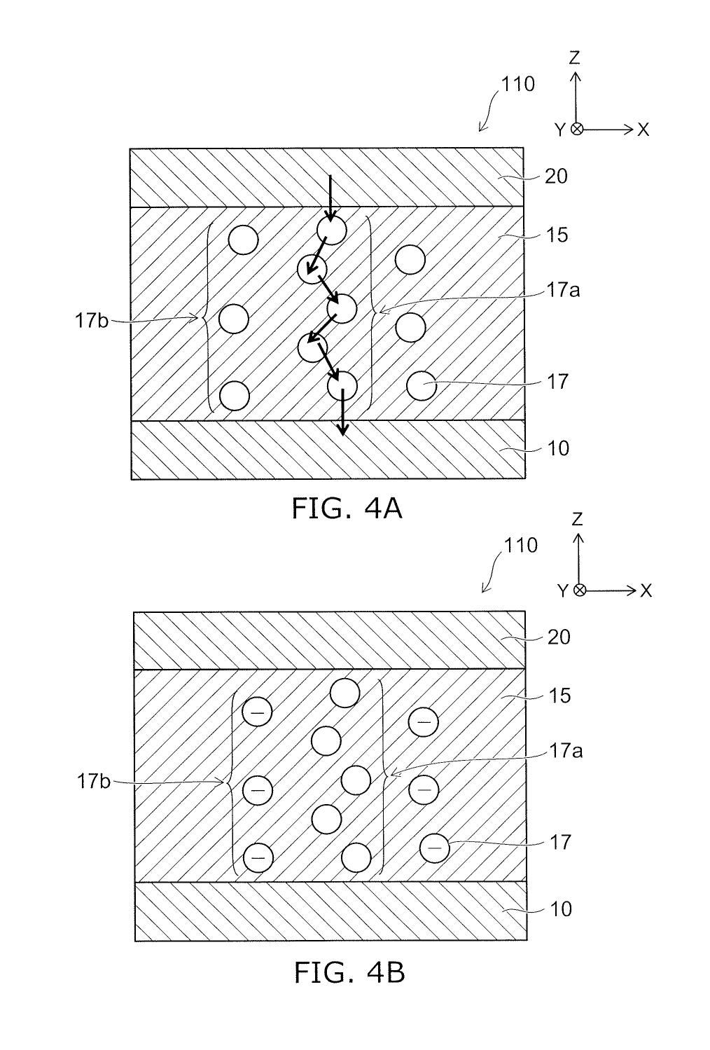

FIG. 4A and FIG. 4B are schematic views showing other characteristics of the nonvolatile memory device according to the first embodiment.

In the nonvolatile memory device 110 as shown in FIG. 4A, a filament-like electronic conduction also may occur via the trap levels originating at the micro particles 17 inside the polyimide film 16. Here, one group of the multiple micro particles 17 that performs a filament-like electronic conduction is taken as a first group 17a; and one other group in the region around the first group 17a that does not perform a filament-like electronic conduction is taken as a second group 17b.

In the case where the storage layer 15 is in the untrapped state as shown in FIG. 4A, the filament-like electronic conduction occurs due to the micro particles 17 included in the first group 17a. In the first group 17a, the electrons move between the trap levels by tunneling.

In the case where the storage layer 15 is in the trapped state as shown in FIG. 4B, the tunneling between the trap levels in the first group 17a is suppressed by the Coulomb repulsion due to the charged micro particles 17 included in the second group 17b. Thus, even in the case of the filament-like electronic conduction, the storage layer 15 is in the low resistance state when in the untrapped state; and the storage layer 15 is in the high resistance state when in the trapped state.

In the case of the filament-like electronic conduction, both the trap level that supports the memory-like property and the level that supports the electronic conduction inside the film are levels that originate at the micro particles 17. However, the two levels exist at spatially different positions inside the film. Which of the micro particles 17 will support the filament conduction is determined by the arrangement of the micro particles 17 of the storage layer 15 in the initial deposition, the rearrangement of the micro particles 17 due to a voltage application, etc. There are cases where it is necessary to apply an initial voltage that is larger than the memory operation voltage to rearrange the micro particles 17 of the storage layer 15 of the initial deposition (forming).

Hereinabove, the case is described where the carriers that are injected from the second conductive unit 20 into the polyimide film 16 are electrons; and the traps due to the micro particles 17 are electron traps.

In the case where the carriers that are injected from the second conductive unit 20 into the polyimide film 16 are holes and the traps due to the micro particles 17 are hole traps, the untrapped state is the low resistance state; and the trapped state (the state of being positively charged) is the high resistance state. The HOMO level of the storage layer 15 changes due to the Coulomb force due to the trap level being positively charged; and the hole injection and conduction is suppressed. In such a case as well, filament-like conduction is possible in addition to a hole conduction that is uniform in the film plane of the storage layer 15.

By material selection, the case is possible where the positive/negative signs of the carriers are different from the signs of the charge traps such as the case where both electrons and holes contribute as carriers inside the storage layer 15, etc. In such a case, in the case where the sign of the majority carrier and the sign of the charged traps are the same, the state in which the traps are charged is the high resistance state because the current is smaller than in the case where the traps are neutral. Conversely, in the case where the sign of the majority carrier and the sign of the charged traps are reverse signs, the state in which the traps are charged is the low resistance state because the current is larger than in the case where the traps are neutral. In either case, in addition to the carrier conduction that is uniform in the film plane of the storage layer 15, filament-like conduction is possible.

It is necessary for the micro particles 17 not to move inside the polyimide film 16 at the memory operation voltage to repeatedly and stably express the memory characteristics due to the trapping and releasing of the carriers in and from the trap levels originating at the micro particles 17. It is also desirable for the distribution of the energy levels originating at the micro particles 17 to be small.

However, because the polyimide film 16 which is the main material is substantially an amorphous material, there is generally a tendency for the micro particles 17 to diffuse or drift easily inside the polyimide film 16. Also, there is a tendency for the energy levels of the micro particles 17 to have a large distribution because the micro particles 17 have various arrangements with respect to the polyimide molecules.

As a result of diligent efforts, the inventors of the application discovered that the interaction between the micro particles 17 and a specific section of the first polyimide can be actively utilized by selecting various inorganic or organic materials that are acceptors or donors and have sizes of not more than substantially 1 nm as the micro particles 17. Then, as a result, it was discovered that the movement of the micro particles 17 inside the polyimide film 16 can be suppressed and the arrangement of the micro particles 17 can be homogeneous.

In particular, the charge-transfer interaction between the micro particles 17 and the donor section of the first polyimide made from the first aromatic diamine molecule is easier. Also, the charge-transfer interaction between the micro particles 17 and the acceptor section made from the first aromatic tetracarboxylic dianhydride molecule is easier. It was discovered that, by actively utilizing such charge-transfer interactions, the movement of the micro particles 17 inside the polyimide film 16 can be suppressed and the arrangement of the micro particles 17 inside the polyimide film 16 can be homogeneous. As a result, in the nonvolatile memory device 110 according to the embodiment, the trapping and releasing of the carriers in and from the trap levels are repeatedly stable; and good switching characteristics as a memory material are possible.

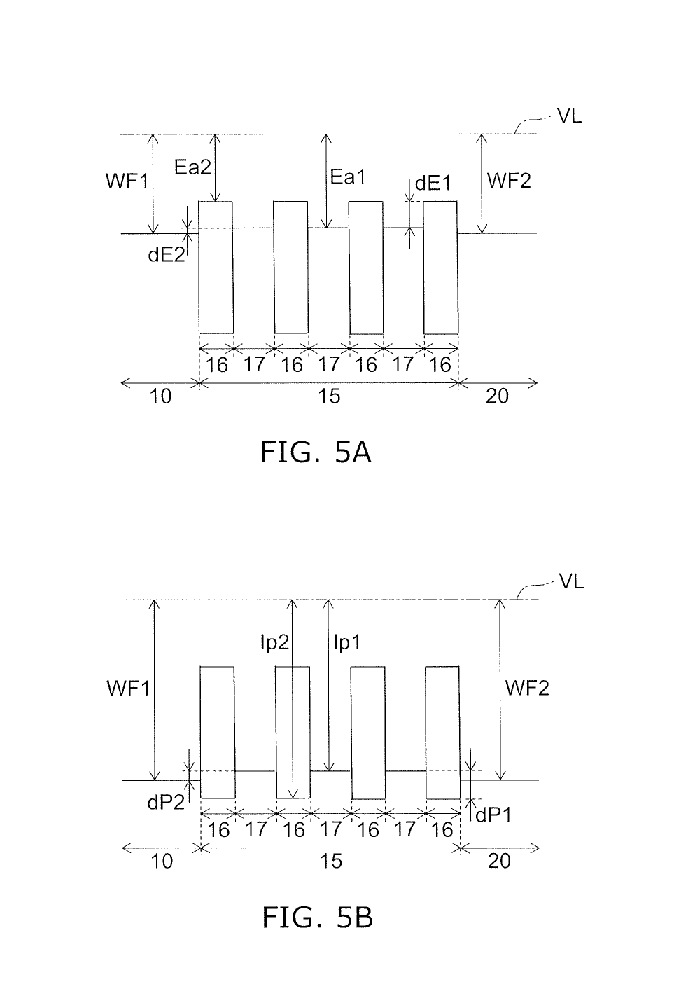

FIG. 5A and FIG. 5B are band diagrams showing characteristics of the nonvolatile memory device according to the first embodiment.

FIG. 5A and FIG. 5B show the relationship between the energy levels having a vacuum level VL as a reference and the thickness-direction position from the first conductive unit 10 toward the second conductive unit 20 of the nonvolatile memory device 110. FIG. 5A is an example using acceptor micro particles 17; and FIG. 5B is an example using donor micro particles 17.

FIG. 5A and FIG. 5B show the state in which a voltage is not applied between the first conductive unit 10 and the second conductive unit 20 (the state in which the potential difference between the first conductive unit 10 and the second conductive unit 20 is small). In FIG. 5A and FIG. 5B, the storage layer 15 is in the untrapped state. FIG. 5A and FIG. 5B show the state in which three micro particles 17 exist between the first conductive unit 10 and the second conductive unit 20. Actually, many micro particles 17 exist between the first conductive unit 10 and the second conductive unit 20.

In the case where the micro particles 17 are acceptors as shown in FIG. 5A, a first electron affinity Ea1 of the micro particles 17 is larger than a second electron affinity Ea2 of the polyimide film 16 in the state in which a voltage is not applied between the first conductive unit 10 and the second conductive unit 20. The absolute value of the difference dE1 between the first electron affinity Ea1 and the second electron affinity Ea2 is, for example, not less than 0.5 eV and not more than 3.0 eV. For example, the absolute value of the difference between the electron affinity of the first polyimide and the electron affinity of the second polyimide is not less than 0.5 eV and not more than 3.0 eV; and the absolute value of the difference between the electron affinity of the first polyimide and the electron affinity of the first organic molecule is not less than 0.5 eV and not more than 3.0 eV.

A first work function WF1 of the first conductive unit 10 is, for example, not less than 4.0 eV and not more than 5.5 eV. A second work function WF2 of the second conductive unit 20 is, for example, not less than 4.0 eV and not more than 5.5 eV. The first electron affinity Ea1 is, for example, not less than 3.0 eV and not more than 4.5 eV. The second electron affinity Ea2 is, for example, not less than 2.0 eV and not more than 4.0 eV. The absolute value of the difference dE2 between the first work function WF1 and the first electron affinity Ea1 is, for example, not more than 1 eV.

In the case where the micro particles 17 are donors as shown in FIG. 5B, a first ionization potential Ip1 of the micro particles 17 is smaller than a second ionization potential Ip2 of the polyimide film 16 in the state in which a voltage is not applied between the first conductive unit 10 and the second conductive unit 20. The absolute value of the difference dP1 between the first ionization potential Ip1 and the second ionization potential Ip2 is, for example, not less than 0.5 eV and not more than 3.0 eV. For example, the absolute value of the difference between the ionization potential of the first polyimide and the ionization potential of the third polyimide is not less than 0.5 eV and not more than 3.0 eV; and the absolute value of the difference between the ionization potential of the first polyimide and the ionization potential of the second organic molecule is not less than 0.5 eV and not more than 3.0 eV.

The first ionization potential Ip1 is, for example, not less than 4.5 eV and not more than 6.5 eV. The second ionization potential Ip2 is, for example, not less than 6.0 eV and not more than 8.0 eV. The absolute value of the difference dP2 between the first work function WF1 and the first ionization potential Ip1 is, for example, not more than 1 eV.

Various substances have been proposed as the memory substances of nonvolatile memory devices, including an organic memory having an interposed organic substance that may be easy to pattern, may have a small current value, and may have low power consumption when the density is high. In particular, an organic substance in which PCBM, which is a fullerene derivative, is dispersed in a polyimide thin film having a high thermal stability has been proposed. However, a ReRAM using a polyimide thin film in which PCBM is dispersed has the disadvantage that the operating current is large. Also, memory in which metal nanoparticles are dispersed in various polymers have been proposed; and operations at relatively low currents have been reported. However, because metal nanoparticles are large and have sizes of about several nm, it is necessary to increase the memory cell surface area to uniformly disperse the nanoparticles to provide uniform memory characteristics; and applications in fine memory cells have been difficult.

The inventors of the application achieved the nonvolatile memory device 110 according to the embodiment by discovering the relationship between the electronic properties and the memory characteristics in the case where various substances are added and dispersed in polyimide source materials having high thermal stabilities. In the nonvolatile memory device 110 according to the embodiment, electrons or holes are trapped at the micro particles 17 having a size of less than 1 nm. Thereby, in the nonvolatile memory device 110, the micro particles 17 can be uniformly dispersed in the polyimide film 16 even in the case where the surface area of the memory cell is set to be not more than 10³ nm². In the nonvolatile memory device 110, the fluctuation of the memory characteristics can be suppressed even in the case of a higher bit density. Thus, in the nonvolatile memory device 110, the uniformity of the memory characteristics can be increased; and the bit density can be increased. According to the nonvolatile memory device 110 according to the embodiment, a high-density resistance change nonvolatile memory device in which the thermal stability is high, the voltage is low, the power consumption is low, and the repetition tolerance is good can be provided.

In the nonvolatile memory device 110, the absolute value of the difference dE1 between the first electron affinity Ea1 and the second electron affinity Ea2 is set to be not less than 0.5 eV and not more than 3.0 eV. By setting the difference dE1 to be not less than 0.5 eV, the effects of thermal excitation, etc., can be suppressed; and the micro particles 17 can have sufficient electron trapping performance. By setting the difference dE1 to be not more than 3.0 eV, the electrons can be appropriately discharged from the micro particles 17 when a reverse voltage is applied.

In the nonvolatile memory device 110, the absolute value of the difference dE2 between the first work function WF1 and the first electron affinity Ea1 is set to be not more than 1 eV. Thereby, the power consumption of the nonvolatile memory device 110 can be reduced. In the case where the difference dE2 is greater than 1 eV, the movement of the electrons from the first conductive unit 10 into the micro particles 17 becomes difficult. Thereby, the drive voltage of the nonvolatile memory device 110 undesirably increases.

In the nonvolatile memory device 110, the bandgap of the polyimide film 16 is set to be not less than 3 eV. Thereby, in the nonvolatile memory device 110, the occurrence of leak current can be suppressed; and the power consumption can be reduced. Also, the occurrence of switching can be suppressed.

In the nonvolatile memory device 110, the first work function WF1 of the second conductive unit 20 is set to be not less than 4.0 eV and not more than 5.5 eV. By setting the first work function WF1 to be not less than 4.0 eV, oxidization of the second conductive unit 20 can be suppressed; and the stability of the electron injection can be increased. By setting the first work function WF1 to be not more than 5.5 eV, the energy gap to the micro particles 17 can be suppressed.

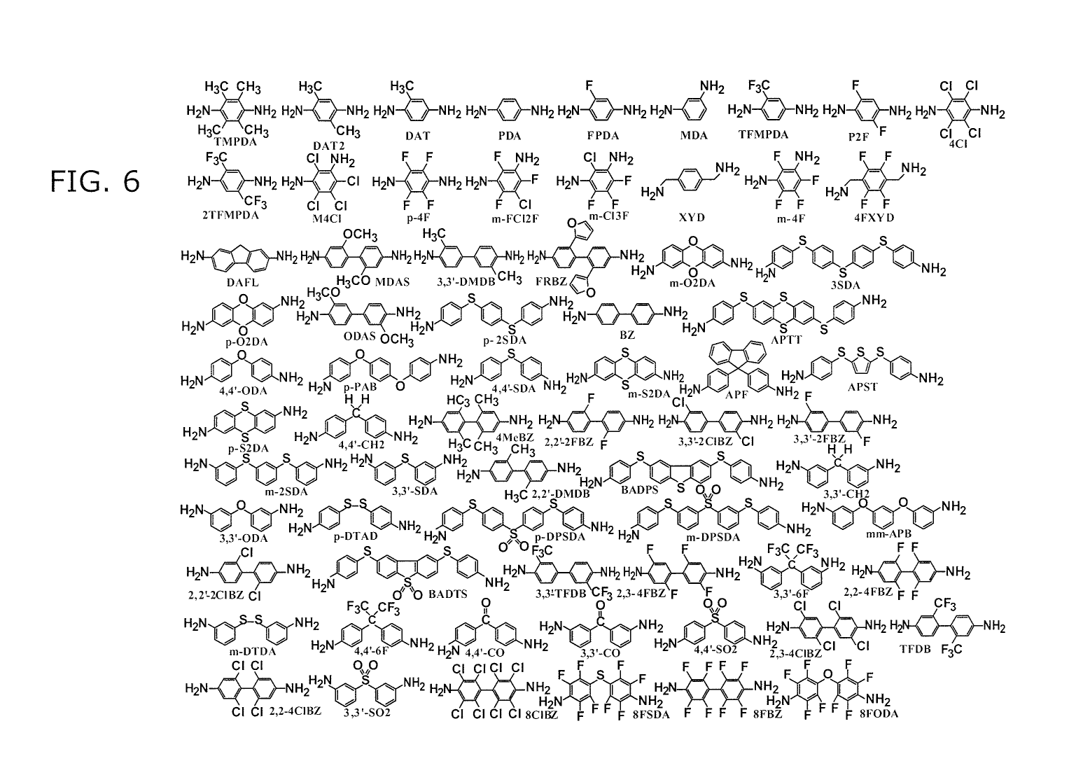

FIG. 6 shows chemical formulas of some materials of the nonvolatile memory device according to the first embodiment.

FIG. 6 shows the chemical formulas and abbreviations of first aromatic diamine molecules used in the polyimide film 16.

As shown in FIG. 6, the first aromatic diamine molecule of the polyimide film 16 may include, for example, at least one selected from DAFL (6.5 eV), MDAS (6.6 eV), TMPDA (6.6 eV), 3,3′-DMDB (6.6 eV), FRBZ (6.6 eV), m-O2DA (6.6 eV), 3SDA (6.6 eV), p-O2DA (6.7 eV), ODAS (6.7 eV), 2SDA (6.7 eV), BZ (6.7 eV), APTT (6.7 eV), 4,4′-ODA (6.8 eV), ppAPB (6.8 eV), 4,4′-SDA (6.8 eV), DAT (6.8 eV), m-S2DA (6.9 eV), APF (6.9 eV), APST (6.9 eV), DAT (6.9 eV), pS2DA (6.9 eV), 4,4′-CH2 (6.9 eV), 4MeBZ (7.0 eV), 2,2′-DFBZ (7.0 eV), 3,3′-DCIBZ (7.0 eV), PDA (7.0 eV), 3,3′-DFBZ (7.0 eV), m-2SDA (7.1 eV), 3′-SDA (7.1 eV), 2,2′-DMDB (7.1 eV), BADPS (7.1 eV), 3,3′-CH2 (7.1 eV), 3,3′-ODA (7.1 eV), pDTDA (7.1 eV), pDPSDA (7.2 eV), mDPSDA (7.2 eV), mmAPB (7.2 eV), 2,2′-DCIBZ (7.2 eV), BADTS (7.3 eV), FPDA (7.3 eV), PANS (7.3 eV), 3,3′-TFDB (7.3 eV), 2,3-4FBZ (7.4 eV), 3,3′-6F (7.4 eV), 4FBZ (7.4 eV), mDTDA (7.4 eV), MDA (7.4 eV), 4,4′-6F (7.4 eV), 4,4′-CO (7.4 eV), TFMPDA (7.4 eV), 3,3′-CO (7.4 eV), p-2F (7.5 eV), 4,4′-SO2 (7.5 eV), 2,3-4CIBZ (7.5 eV), TFDB (7.6 eV), p-4CI (7.6 eV), 4CIBZ (7.7 eV), MANS (7.7 eV), 3,3′-SO2 (7.7 eV), 8CIBZ (7.8 eV), 2TFMPDA (7.8 eV), m-4Cl (7.8 eV), p-4F (7.9 eV), 8FSDA (7.9 eV), 8FBZ (8.0 eV), MFCI2F (8.0 eV), MCI3F (8.0 eV), 8FODA (8.0 eV), XYD (8.1 eV), m-4F (8.1 eV), and 4FXYD (8.9 eV).

The numerical values inside the parentheses of the first aromatic diamine molecules recited above are the ionization potentials.

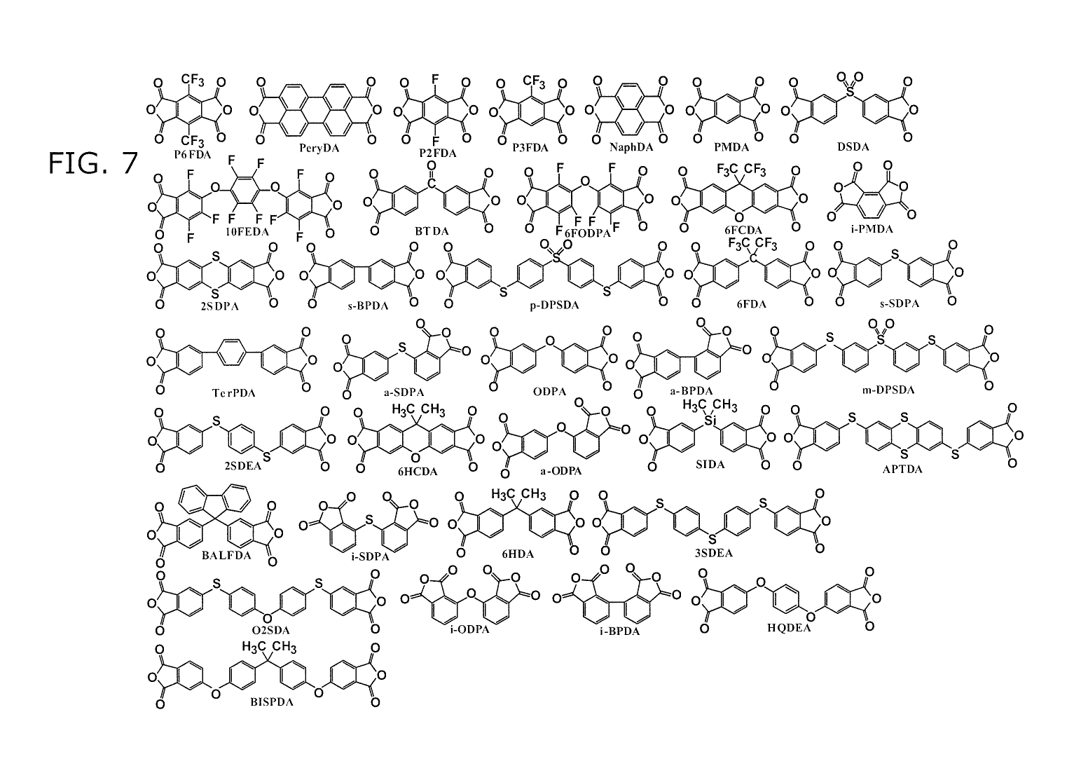

FIG. 7 shows chemical formulas of some materials of the nonvolatile memory device according to the first embodiment.

FIG. 7 shows the chemical formulas and abbreviations of first aromatic tetracarboxylic dianhydride molecules used in the polyimide film 16.

As shown in FIG. 7, the first aromatic tetracarboxylic dianhydride molecule of the polyimide film 16 may include, for example, at least one selected from P6FDA (4.7 eV), PeryDA (3.0 eV), P2FDA (3.0 eV), P3FDA (2.9 eV), NaphDA (2.9 eV), PMDA (2.6 eV), DSDA (2.6 eV), 10FEDA (2.6 eV), BTDA (2.6 eV), s-6FODPA (2.5 eV), 6FCDA (2.4 eV), i-PMDA (2.3 eV), 2SDPA (2.3 eV), s-BPDA (2.2 eV), pDPSDA (2.2 eV), 6FDA (2.2 eV), s-SDPA (2.2 eV), TerPDA (2.2 eV), a-SDPA (2.1 eV), s-ODPA (2.1 eV), a-BPDA (2.0 eV), mDPSDA (2.0 eV), 2SDEA (2.0 eV), 6HCDA (2.0 eV), a-ODPA (2.0 eV), SIDA (2.0 eV), APTDA (2.0 eV), BAFLDA (2.0 eV), i-SDPA (1.9 eV), 6HDA (1.9 eV), 3SDEA (1.9 eV), O2SDEA (1.9 eV), i-ODPA (1.9 eV), i-BPDA (1.9 eV), HQDEA (1.9 eV), and BISPDA (1.8 eV).

The numerical values inside the parentheses of the first aromatic tetracarboxylic dianhydride molecules recited above are the electron affinities.

The metal atom used as the micro particle 17 may include, for example, at least one selected from Sc, Ti, V, Cr, Mn, Fe, Co, Ni, Cu, Zn, Y, Zr, Nb, Mo, Ru, Rh, Pd, Ag, Cd, Hf, Ta, W, Re, Os, Ir, Pt, Au, Bi, Li, Na, K, Rb, Cs, Be, Mg, Ca, Sr, Ba, and lanthanoid. The metal ion may be an ion of at least one selected from the metal atoms recited above. It is more favorable for the metal atom or the metal ion to include at least one selected from Au, Ag, Cu, Ni, and Pt. It is optimal for the metal atom or the metal ion to be Au.

The metal atom or the metal ion is unclustered. In other words, the metal atom or the metal ion is not a metal nanoparticle. The metal atom or the metal ion is, for example, isolated. The metal atom or the metal ion being unclustered can be confirmed by, for example, the following method. First, the metal content inside the thin film of the first polyimide is confirmed by EDX (Energy Dispersive X-ray Spectroscopy). Then, a light absorption measurement of the thin film of the first polyimide is performed; and the existence/absence of the metal nanoparticle inside the thin film of the first polyimide is confirmed by the existence/absence of surface plasmon resonance absorption in the near-ultraviolet to near-infrared region that is characteristic of the metal nanoparticle. In the case where it is confirmed by EDX that a metallic element is contained and the surface plasmon resonance absorption that is characteristic of the metal nanoparticle is not confirmed by the light absorption measurement, it is confirmed that unclustered metal atoms or unclustered metal ions are included in the thin film of the first polyimide.

The section of the first polyimide, which is the main material, that originates at the first aromatic tetracarboxylic dianhydride molecule may be an acceptor. Therefore, the metal atom attempts to form a weak charge-transfer salt with the section of the first polyimide originating at the first aromatic tetracarboxylic dianhydride molecule that is acceptor-like. As a result, the movement of the metal atom can be suppressed because the position occupied by the metal atom inside the polyimide film 16 is substantially fixed. Also, the trap level homogeneity improves.

The acceptor-like property of the section of the first polyimide originating at the first aromatic tetracarboxylic dianhydride molecule is not very strong. Therefore, the charge transfer with the metal atom is partial because one electron does not completely move and is nearly neutral (the electron does not move). This indicates the average transfer charge amount when observing at a long time scale corresponding to an energy scale that is smaller than the energy scale of the charge-transfer interaction between the section and the metal atom. Because the metal atom is substantially neutral at a short time scale, the trapping of the holes in the trap level is not obstructed even in the case where partial charge transfer with the polyimide occurs.

After trapping the charge, the metal ion stabilizes somewhat due to the opposing negative charge occurring in the acceptor section due to the intramolecular charge transfer inside the polyimide molecules. The metal atom can exist at a high density inside the polyimide film 16 without disturbing the polyimide structure of the main body because the size of the metal atom is extremely small and is about 0.1 nm. As a result, the Coulomb force due to the positively-charged traps is large; and the current in the high resistance state can be greatly reduced. In other words, the current on/off ratio as a memory increases.

The formation of the weak charge-transfer salt between the metal atom and the section of the first polyimide originating at the first aromatic tetracarboxylic dianhydride molecule can be confirmed as follows. It can be confirmed by the appearance of a charge-transfer absorption band (CT band) originating at the charge-transfer salt in the near-ultraviolet to near-infrared region in the light absorption measurement. Or, a molecular vibration mode attributed to the section of the first polyimide originating at the first aromatic tetracarboxylic dianhydride molecule is observed by infrared absorption or Raman scattering measurements. Thereby, confirmation is also possible by observing the shift of the frequency due to the partial charge transfer due to the charge-transfer salt formation.

The second aromatic tetracarboxylic dianhydride molecule of the second polyimide used as the micro particle 17 includes an aromatic tetracarboxylic dianhydride molecule having a larger electron affinity than the first aromatic tetracarboxylic dianhydride molecule of the first polyimide. The LUMO of the second polyimide mainly originates at the LUMO of the second aromatic tetracarboxylic dianhydride molecule. Therefore, due to the aromatic tetracarboxylic dianhydride molecule having the large electron affinity that is used as the second aromatic tetracarboxylic dianhydride molecule, the electron affinity of the second polyimide becomes greater than the electron affinity of the first polyimide. Thereby, the LUMO of the second polyimide is positioned inside the bandgap of the first polyimide; and the LUMO of the second polyimide functions as the trap level.

The third aromatic diamine molecule of the third polyimide used as the micro particle 17 includes an aromatic diamine molecule having a smaller ionization potential than the first aromatic diamine molecule of the first polyimide. The HOMO of the third polyimide mainly originates at the HOMO of the third aromatic diamine molecule. Therefore, the ionization potential of the third polyimide becomes less than the ionization potential of the first polyimide due to the aromatic diamine molecule having the small ionization potential that is used as the third aromatic diamine molecule. Thereby, the HOMO of the third polyimide is positioned inside the bandgap of the first polyimide; and the HOMO of the third polyimide functions as the trap level.

The first organic molecule used as the micro particle 17 may include, for example, at least one selected from tetracyanoquinodimethane (TCNQ, 2.8 eV), TCNQ derivative, dicyanoquinonediimine (DCNQI, 2.7 eV), DCNQI derivative, benzoquinone (BQ), BQ derivative (p-BQ, 1.9 eV), 2,3-naphthoquinone (2.2 eV), tetracyanonaphtho quinodimethane (2.9 eV), tetracyanoethylene (2.4 eV), tetracyanobenzene (1.8 eV), hexacyanobenzene (2.2 eV), fluorene derivative, tetracarboxylic dianhydride, and hexadecafluoro copper phthalocyanine (3.0 eV). The TCNQ derivative may include, for example, 2-methyl-TCNQ (2.7 eV), 2-alkyl-TCNQ (2.7 eV), 2,5-dimethyl-TCNQ (2.7 eV), 2,5-dichloro-TCNQ (3.0 eV), 2,3,5,6-tetrafluoro-TCNQ (3.4 eV), etc. The DCNQI derivative may include, for example, 2,5-dimethyl-DCNQI (2.7 eV), 2,5-dichloro-DCNQI (2.9 eV), etc. The BQ derivative may include, for example, 2,5-dichloro-p-BQ (2.4 eV), p-chloranil (2.8 eV), p-fluoranil (2.6 eV), p-bromanil (2.4 eV), 2,3-dichloro-5,6-dicyano-p-BQ (DDQ, 3.2 eV), etc. The fluorene derivative may include, for example, 2,4,7-trinitrofluorenone (2.0 eV), dicyanomethylene-2,4,7-trinitrofluorene (2.6 eV), etc. The tetracarboxylic dianhydride may include, for example, PerDA (3.0 eV), PMDA (2.6 eV), etc.

The size of each of these acceptor organic molecules is small and is less than substantially 1 nm. Therefore, the first organic molecules can be dispersed uniformly in the polyimide film 16 having a micro cell volume; and the uniformity of the memory cell characteristics can be realized. The numerical values inside the parentheses of the first organic molecules recited above are the electron affinities. Here, the value of the electron affinity is the value for an isolated molecule in the vapor phase or in solution; and the value of the electron affinity inside the polyimide film is greater due to the effect of the polarization energy.

The acceptor first organic molecule may be used as the micro particle 17. In such a case, the degrees of freedom of the molecular design of the organic molecule are high. Therefore, not only can various molecular design be performed to improve the dispersibility, but also the LUMO level (the electron affinity) that forms the trap level can be adjusted in detail. Further, the molecular orbital configuration can be finely controlled.

The section of the first polyimide, which is the main material, that originates at the first aromatic diamine molecule may be a donor. Therefore, the first organic molecule causes the molecular surface to oppose the section of the first polyimide originating at the first aromatic diamine molecule and causes a partial charge transfer to occur between the section and the molecular surface. Thereby, the first organic molecule attempts to form a donor/acceptor-type weak charge-transfer complex. As a result, the position occupied by the first organic molecule inside the polyimide film 16 is substantially fixed. The movement of the first organic molecule is suppressed. Also, the trap level homogeneity drastically improves.

The donor-like property of the section of the first polyimide originating at the first aromatic diamine molecule is not very strong. Therefore, the charge transfer with the first organic molecule is partial because one electron does not completely move and is nearly neutral (the electron does not move). This indicates the average transfer charge amount when observing at a time scale corresponding to an energy scale that is smaller than the energy scale of the charge-transfer interaction of the section and the first organic molecule. The first organic molecule is substantially neutral at a short time scale. Therefore, the trapping of the electrons in the trap level is not obstructed even in the case where the partial charge transfer with the polyimide occurs. After trapping the charge, the first organic molecule ion stabilizes somewhat due to the opposing positive charge occurring in the donor section due to the intramolecular charge transfer inside the polyimide molecules.

It is also possible to select a molecule that may have polyvalent ion states as the first organic molecule. In such a case, the Coulomb force due to the polyvalently negatively-charged traps becomes large; and the current in the high resistance state can be greatly reduced. In other words, the current on/off ratio as a memory increases.

The occurrence of the partial charge transfer between the first organic molecule and the section of the first polyimide originating at the first aromatic diamine molecule can be confirmed as follows. It can be confirmed by the appearance of a charge-transfer absorption band (CT band) originating at the charge-transfer complex in the visible to near-infrared region in the light absorption measurement. Or, a molecular vibration mode attributed to the acceptor organic molecule or the section of the first polyimide originating at the first aromatic diamine molecule is observed by infrared absorption or Raman scattering measurements. Thereby, it is also possible to confirm by observing the shift of the frequency due to the partial charge transfer.

The second organic molecule used as the micro particle 17 may include, for example, at least one selected from tetrathiafulvalene (TTF, 6.4 eV), TTF derivative, tetrathianaphthacene (6.1 eV), phenylenediamine, phenylenediamine derivative, naphthalenediamine (6.7 eV), phenothiazine (6.7 eV), 5,10-dimethyl 5,10-dihydrophenazine (6.0 eV), polycyclic aromatic hydrocarbon, metallocenes, phthalocyanines, porphyrins, and tetrakis-dimethylamino-ethylene (TDAE, 5.4 eV). The TTF derivative may include, for example, at least one selected from DMTTF (6.0 eV), TMTTF (6.0 eV), HMTTF (6.1 eV), TTMTTF (6.3 eV), BEDT-TTF (6.2 eV), DBTTF (6.7 eV), TSF (6.7 eV), TMTSF (6.3 eV), HMTSF (6.1 eV), HMTTeF (6.8 eV), and tetrakis-alkylthia-TTF (alkyl being the alkyl groups from ethyl to octadecyl, 6.0 eV to 6.8 eV). The phenylenediamine derivative may include, for example, at least one selected from N,N,N′,N′-tetramethyl-p-phenylenediamine (TMPD, 6.2 eV), 2,3,5,6-tetramethyl-p-phenylenediamine (TMPDA, 6.6 eV), and p-phenylenediamine (PDA, and 7.0 eV). The polycyclic aromatic hydrocarbon may include, for example, at least one selected from naphthacene (6.9 eV), pentacene (6.6 eV), hexacene (6.4 eV), pyrene (7.4 eV), perylene (6.9 eV), coronene (7.3 eV), violanthrene (6.4 eV), tetrabenzoperylene (6.6 eV), tetrabenzopentacene (6.1 eV), ovalene (6.9 eV), quaterrylene (6.1 eV), and rubrene (6.4 eV). The metallocenes may include, for example, at least one selected from ferrocene (6.7 eV), decamethylferrocene (5.7 eV), nickelocene (6.2 eV), decamethylnickelocene (4.4 eV), ruthenocene (6.2 eV), and cobaltocene (6.4 eV). The phthalocyanines may include, for example, at least one selected from phthalocyanine (6.1 eV) and metal phthalocyanine (6.1 eV to 6.2 eV). The metal of the metal phthalocyanine may include, for example, at least one selected from Cu, Fe, Pb, Mg, Ni, Zn, and Co. The porphyrins may include, for example, at least one selected from tetraphenylporphine (TPP, 6.4 eV), Zn-TPP (6.2 eV), and Mg-TPP (6.3 eV).

The size of each of these donor organic molecules is small and is less than substantially 1 nm. Therefore, the second organic molecule can be dispersed uniformly in the polyimide film 16 having the micro cell volume; and the uniformity of the memory cell characteristics can be realized. The numerical values inside the parentheses of the second organic molecules recited above are the ionization potentials. Here, the value of the ionization potential is the value for an isolated molecule in the vapor phase or in solution; and the value of the ionization potential due to the effect of the polarization energy inside the polyimide film is even smaller.

The degrees of freedom of the molecular design of the organic molecule are high in the case where the second organic molecule is used as the micro particle 17. Therefore, not only can various molecular design be performed to improve the dispersibility, but also the HOMO level (the ionization potential) that forms the trap level can be adjusted in detail. It is also possible to finely control the molecular orbital configuration.

The section of the first polyimide, which is the main material, that originates at the first aromatic tetracarboxylic dianhydride molecule may be an acceptor. Therefore, the second organic molecule causes the molecular surface to oppose the section of the first polyimide originating at the first aromatic tetracarboxylic dianhydride molecule and causes a partial charge transfer to occur between the section and the molecular surface. Thereby, the second organic molecule attempts to form a donor/acceptor-type weak charge-transfer complex. As a result, the position occupied by the second organic molecule inside the polyimide film 16 is substantially fixed. The movement of the second organic molecule is suppressed. Also, the trap level homogeneity can be improved.

The acceptor-like property of the section of the first polyimide originating at the first aromatic tetracarboxylic dianhydride molecule is not very strong. Therefore, the charge transfer with the second organic molecule is partial because one electron does not completely move and is nearly neutral (the electron does not move). This indicates the average transfer charge amount when observing at a time scale corresponding to an energy scale that is smaller than the energy scale of the charge-transfer interaction of the section and the second organic molecule. The trapping of the holes in the trap level is not obstructed even in the case where the partial charge transfer with the polyimide occurs because the second organic molecule is substantially neutral at a short time scale. After trapping the charge, the second organic molecule ion stabilizes somewhat due to the opposing negative charge occurring in the acceptor section due to the intramolecular charge transfer inside the polyimide molecules.

It is also possible to select a molecule that may have polyvalent ion states as the second organic molecule. In such a case, the Coulomb force due to the polyvalently positively-charged traps becomes large; and the current in the high resistance state can be greatly reduced. In other words, the current on/off ratio as a memory increases. The molecule that may have such a polyvalent ion state may include, for example, phthalocyanines, porphyrins, etc.

The occurrence of the partial charge transfer between the second organic molecule and the section of the first polyimide originating at the first aromatic tetracarboxylic dianhydride molecule can be confirmed as follows. It can be confirmed by the appearance of a charge-transfer absorption band (CT band) originating at the charge-transfer complex in the visible to near-infrared region in the light absorption measurement. Or, a molecular vibration mode attributed to the second organic molecule or the section of the first polyimide originating at the first aromatic tetracarboxylic dianhydride molecule is observed by infrared absorption or Raman scattering measurements. Thereby, it is also possible to confirm by observing the shift of the frequency due to the partial charge transfer.

The inorganic compound used as the micro particle 17 may include, for example, at least one selected from a halogen, a Lewis acid, a proton acid, a transition metal compound, an electrolyte anion, XeOF₄, FSO₂OOSO₂F, AgClO₄, H₂IrCl₆, and La(NO₃)₃.6H₂O. The halogen may include, for example, Cl₂, Br₂, I₂, ICl, ICl₃, IBr, IF, etc. The Lewis acid may include, for example, PF₅, AsF₅, SbF₅, BF₃, BCl₃, BBr₃, SO₃, etc. The proton acid may include, for example, HF, HCl, HNO₃, H₂SO₄, HClO₄, FSO₃H, CISO₃H, CF₃SO₃H, etc. The transition metal compound may include, for example, FeCl₃, FeOCl, TiCl₄, ZrCl₄, HfCl₄, NbF₅, NbCl₅, TaCl₅, MoF₅, MoCl₅, WF₆, WCl₆, UF₆, LnCl₃ (Ln being a lanthanoid such as La, Ce, Pr, Nd, Sm, or the like), etc. The electrolyte anion may include, for example, Cl⁻, Br⁻, I⁻, ClO₄⁻, PF₆⁻, AsF₆⁻, SbF₆⁻, BF₄⁻, etc.

The size of each of these acceptor inorganic compounds is small and is less than substantially 1 nm. Therefore, the inorganic compound can be dispersed uniformly in the polyimide film 16 having the micro cell volume; and the uniformity of the memory cell characteristics can be realized.

The section of the first polyimide, which is the main material, that originates at the first aromatic diamine molecule may be a donor. Therefore, the inorganic compound attempts to form a weak charge-transfer salt with the section of the first polyimide originating at the first aromatic diamine molecule. As a result, the position occupied by the inorganic compound inside the polyimide film 16 is substantially fixed. The movement of the inorganic compound is suppressed. Also, the trap level homogeneity can be drastically improved.

It is possible to select an inorganic compound that is small and has a size of about 0.3 nm. Therefore, the inorganic compound can exist at a high density inside the polyimide film without disturbing the polyimide structure of the main body. As a result, the Coulomb force due to the negatively-charged traps becomes large; and the current in the high resistance state can be greatly reduced. In other words, the current on/off ratio as a memory increases.

The formation of the charge-transfer salt by the inorganic compound and the section of the first polyimide originating at the first aromatic diamine molecule can be confirmed as follows. It can be confirmed by the appearance of a charge-transfer absorption band (CT band) originating at the charge-transfer salt in the near-ultraviolet to near-infrared region in the light absorption measurement. Or, a molecular vibration mode attributed to the section of the first polyimide originating at the first aromatic diamine molecule is observed by infrared absorption or Raman scattering measurements. Thereby, it is also possible to confirm by observing the shift of the frequency due to the partial charge transfer due to the charge-transfer salt formation.

Although a single type of the micro particle 17 may be used in the polyimide film 16 recited above, multiple types may be used in combination. It is possible to use the micro particles 17 dispersed uniformly inside the polyimide film 16; and it is also possible to use the micro particles 17 selectively dispersed in one portion inside the polyimide film 16. It is also possible to use the micro particles 17 that have a dispersion density that changes such as having a gradient in the dispersion density of the dispersed material inside the polyimide film. For example, in the case of the selective dispersion or in the case of the changing dispersion density, the formation of the polyimide film may be divided into multiple layers; and the dispersion density may be changed for each of the layers.

The first conductive unit 10 and the second conductive unit 20 may include, for example, at least one selected from aluminum (Al), copper (Cu), titanium nitride (TiN), iridium (Ir), iridium oxide (IrOx), ruthenium (Ru), ruthenium oxide (RuOx), platinum (Pt), silver (Ag), gold (Au), poly silicon (Si), tungsten (W), titanium (Ti), tantalum (Ta), tantalum nitride (TaN), tungsten nitride (WN), molybdenum nitride (Mo₂N), nickel (Ni), nickel silicide (NiSi), titanium silicide (TiSi₂), cobalt (Co), chrome (Cr), antimony (Sb), iron (Fe), molybdenum (Mo), palladium (Pd), tin (Sn), zirconium (Zr), zinc (Zn), indium tin oxide (ITO), and carbon (C). Polysilicon, carbon, etc., may be doped with an impurity. It is favorable for the carbon to include, for example, carbon nanotubes, graphene, etc. When making the nonvolatile memory device 110, for example, one selected from the first conductive unit 10 and the second conductive unit 20 is made on a substrate; subsequently, the storage layer 15 is formed; and the other selected from the first conductive unit 10 and the second conductive unit 20 is made on the storage layer 15. The first conductive unit 10 may be made first (on the substrate); or the second conductive unit 20 may be made first.

When making the polyimide film 16, for example, a solution of polyamic acid which is a precursor is made. The solution of polyamic acid is made using a first source material including at least the first aromatic diamine molecule and the first aromatic tetracarboxylic dianhydride molecule. The solution of polyamic acid is coated onto the substrate on which the first conductive unit 10 or the second conductive unit 20 is made. Then, the polyimide film 16 is made by dehydrating and imidizing the solution of polyamic acid that is coated onto the substrate at a high temperature.

The thickness of the polyimide film 16 is, for example, not less than 5 nm and not more than 80 nm. In the case where the thickness of the polyimide film 16 is thinner than 5 nm, leaks occur easily. In the case where the thickness of the polyimide film 16 is thicker than 80 nm, the drive voltage increases. It is more favorable for the thickness of the polyimide film 16 to be, for example, not less than 5 nm and not more than 30 nm. Thereby, the occurrence of leaks and the increase of the drive voltage can be suppressed more appropriately.

The coating method of the solution may include, for example, spin coating, dip coating, Langmuir-Blodgett method, atomization coating, flow coating, screen printing, electrostatic coating, blade coating, roll coating, inkjet printing, etc.

A solvent that is usable when coating the solution is, for example, at least one selected from the group consisting of chloroform, N-methylpyrrolidone, acetone, cyclopentanone, cyclohexanone, methyl ethyl ketone, ethyl cellosolve acetate, butyl acetate, ethylene glycol, toluene, xylene, tetrahydrofuran, dimethylformamide, chlorobenzene, and acetonitrile. One type of material may be used as the solvent; or a mixture of any two or more types of materials may be used.

The method for dispersing the metal atom or the metal ion in the polyimide film 16 may include, for example, immersing in a metal compound solution. The method for immersing in the metal compound solution may include, for example, forming a polyamic acid film on the substrate by coating a polyamic acid solution onto the substrate and removing the solvent from the polyamic acid solution. The metal ion is included in the polyamic acid film by immersing the substrate on which the polyamic acid film is formed in a metal compound solution. The polyamic acid film including the metal ion is dehydrated and imidized at a high temperature. Thereby, the polyimide film 16 including the metal ion is obtained. The metal compound solution may include, for example, a solution in which a metal compound made of a metal salt is dissolved in a solvent, a solution in which a metal compound made of a combination of a metal salt and a ligand is dissolved in a solvent, etc. The metal salt may include, for example, a chloride, a nitrate, a sulfate, a hydroxide, etc. The ligand combined with the metal salt may include, for example, a monodentate ligand, a bidentate ligand, etc. The monodentate ligand may include, for example, ammonia, pyridine, etc. The bidentate ligand may include, for example, ethylene diamine, 2,2′-bipyridyl, 1,10-phenanthrene, etc.

The method for dispersing the metal atom or the metal ion in the polyimide film 16 may include, for example, implanting the metal ion into the polyimide film 16 by ion implantation, or introducing the metal ion into the polyimide film 16 in the initial state by including the metallic element to be dispersed in the first conductive unit 10 or the second conductive unit 20 and applying an electric field.

The method for dispersing the second polyimide in the polyimide film 16 may include, for example, making a mixed solution of a polyamic acid solution that is the precursor of the first polyimide and a polyamic acid solution that is the precursor of the second polyimide and coating the mixed solution onto the substrate. The method for dispersing the second polyimide in the polyimide film 16 may include, for example, alternately and repeatedly performing the coating/baking of the polyamic acid solution that is the precursor of the first polyimide and the coating/baking of the polyamic acid solution that is the precursor of the second polyimide.

The method for dispersing the third polyimide in the polyimide film 16 may be, for example, the same as that of the second polyimide. The coating method of the solution of the second polyimide and the solution of the third polyimide may be, for example, the same as the coating method of the solution of the first polyimide. The solvent of the second polyimide and the solvent of the third polyimide may be, for example, the same material as that of the solvent of the first polyimide.

The method for dispersing the first organic molecule in the polyimide film 16 may include, for example, dissolving the first organic molecule in the polyamic acid solution that is the precursor of the first polyimide. In such a case as well, the coating method and solvent may be the same coating method and solvent as those of the first polyimide. The method for dispersing the second organic molecule in the polyimide film 16 may be the same as that of the first organic molecule.

The method for dispersing the acceptor inorganic compound in the polyimide film 16 may include, for example, chemical doping utilizing a vapor phase or liquid phase. The method for dispersing the inorganic compound in the polyimide film 16 may include, for example, dissolving the inorganic compound in the polyamic acid solution that is the precursor of the first polyimide. In such a case as well, the coating method and solvent may be the same coating method and solvent as those of the first polyimide.

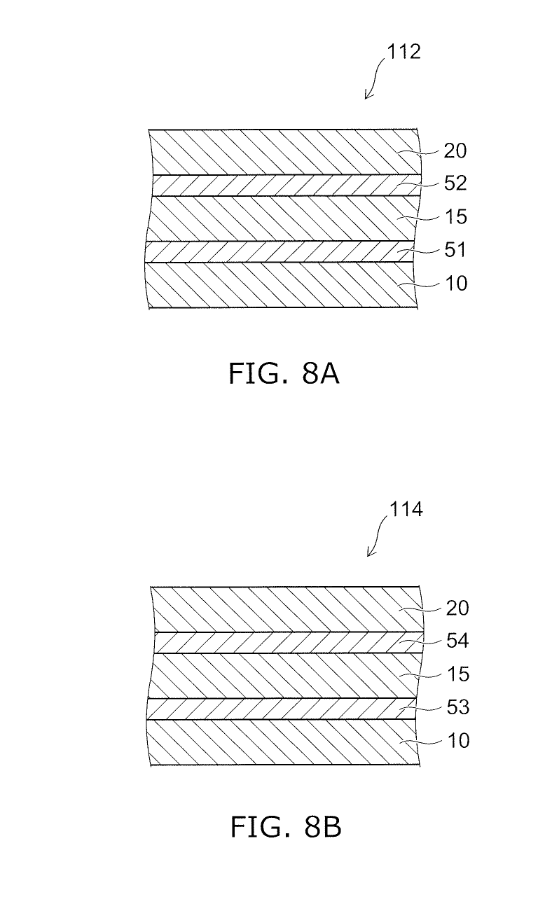

FIG. 8A and FIG. 8B are schematic cross-sectional views showing other nonvolatile memory devices according to the first embodiment.

As shown in FIG. 8A, a nonvolatile memory device 112 further includes a first organic coupling layer 51 and a second organic coupling layer 52.

The first organic coupling layer 51 is provided between the first conductive unit 10 and the storage layer 15. The second organic coupling layer 52 is provided between the second conductive unit 20 and the storage layer 15. The first organic coupling layer 51 suppresses peeling of the first conductive unit 10 from the storage layer 15 including the polyimide film 16 and instability of the transfer of the charge between the first conductive unit 10 and the storage layer 15. The second organic coupling layer 52 suppresses peeling of the second conductive unit 20 from the storage layer 15 and instability of the transfer of the charge between the second conductive unit 20 and the storage layer 15. Only one selected from the first organic coupling layer 51 and the second organic coupling layer 52 may be provided in the nonvolatile memory device 112.

The material of the first organic coupling layer 51 is selected according to, for example, the material of the first conductive unit 10. For example, the first organic coupling layer 51 includes a thiol-type sulfur compound, etc., in the case where the first conductive unit 10 includes a noble metal such as gold, silver, etc. For example, the first organic coupling layer 51 includes a phosphonic acid compound, etc., in the case where the first conductive unit 10 includes a material that forms a surface oxide film such as nickel, chrome, iron, ITO, etc. For example, the first organic coupling layer 51 includes a silane coupling agent, etc., in the case where an oxide of silicon or the like that has a high acidity is provided at the surface of the first conductive unit 10. The material of the second organic coupling layer 52 is set according to the material of the second conductive unit 20. The material of the second organic coupling layer 52 is substantially the same as the material of the first organic coupling layer 51.

As shown in FIG. 8B, a nonvolatile memory device 114 further includes a first oxide film 53 and a second oxide film 54.

The first oxide film 53 is provided between the first conductive unit 10 and the storage layer 15. The second oxide film 54 is provided between the second conductive unit 20 and the storage layer 15. The first oxide film 53 and the second oxide film 54 include, for example, at least one selected from the group consisting of SiOx, AlOx, NiOx, NbOx, TiOx, CrOx, VOx, FeOx, TaOx, CuOx, MgOx, WOx, AlNOx, TiNOx, SiNOx, and TaNOx. It is favorable for the material of the first oxide film 53 and the material of the second oxide film 54 to be, for example, at least one selected from SiOx, Al₂O₃, Cu₂O, NiO, TiO₂, and V₂O₃.

The first oxide film 53 suppresses, for example, nonuniform oxidization of the surface of the first conductive unit 10, etching of the surface of the first conductive unit 10, etc., that occur due to the coating, baking, etc., of the polyamic acid solution when making the storage layer 15. The adhesion between the polyimide film 16 and the first conductive unit 10 also can be increased. Thereby, the first oxide film 53 can suppress the peeling of the first conductive unit 10 from the storage layer 15 and the instability of the transfer of the charge between the first conductive unit 10 and the storage layer 15. The second oxide film 54 increases the adhesion between the polyimide film 16 and the second conductive unit 20 by suppressing, for example, nonuniform oxidization of the surface of the second conductive unit 20, etching of the surface of the second conductive unit 20, etc.

The thickness of the first oxide film 53 and the thickness of the second oxide film 54 are set to be, for example, thicknesses such that sufficient charge can be injected into the storage layer 15. The thickness of the first oxide film 53 and the thickness of the second oxide film 54 change due to, for example, the conductivity of the materials that are used.

Only one selected from the first oxide film 53 and the second oxide film 54 may be provided in the nonvolatile memory device 114. It is sufficient for the first oxide film 53 and the second oxide film 54 to be provided, for example, on at least the one selected from the first conductive unit 10 and the second conductive unit 20 that is formed first on the substrate. In the nonvolatile memory device 114, for example, the first organic coupling layer 51 may be provided between the first oxide film 53 and the storage layer 15; and the second organic coupling layer 52 may be provided between the second oxide film 54 and the storage layer 15.

Examples of the nonvolatile memory device 110 according to the embodiment will now be described.

### First Example

A nickel film having a thickness of 80 nm is formed as the first conductive unit 10 on a silicon substrate on which a silicon oxide film is formed by sputtering nickel on the silicon substrate. A DMF solution of polyamic acid is made from a first source material including p-phenylenediamine (PDA, Ip=7.0 eV) which is the first aromatic diamine molecule and s-BPDA (Ea=2.2 eV) which is the first aromatic tetracarboxylic dianhydride molecule. A polyamic acid film is formed by coating the DMF solution onto the silicon substrate by spin coating and baking at 100° C. The polyamic acid film is immersed in a silver-containing aqueous solution including silver nitrate, water, and aqueous ammonia and heated at 350° C. after rinsing with water and drying. Thereby, the storage layer 15 is formed on the first conductive unit 10. The storage layer 15 includes the polyimide film 16 having a thickness of 10 nm to 15 nm and the micro particles 17 including silver atoms or silver ions. The nonvolatile memory device 110 of the first example is made by forming the second conductive unit 20 by vapor-depositing gold on the storage layer 15.

In the nonvolatile memory device 110 of the first example, the first conductive unit 10 is grounded; and a voltage is applied to the second conductive unit 20. When a positive voltage is applied to the second conductive unit 20, the state is switched to the low resistance state (SET) at about 3.5 V (forming). Then, when a negative voltage is applied to the second conductive unit 20, the state is switched to the high resistance state at about −2 V. When the positive voltage is applied again to the second conductive unit 20, the state is switched to the low resistance state at about 2.5 V; and thereafter, the SET-RESET is repeated. In the state in which a voltage is not applied after being switched to the high resistance state, the high resistance state is substantially retained even after being left for about one week. In the state in which a voltage is not applied after being switched to the low resistance state, the low resistance state is substantially retained even after being left for about one week. Thus, in the nonvolatile memory device 110 of the first example, stable memory characteristics are obtained.

### Second Example

A nickel film having a thickness of 80 nm is formed as the first conductive unit 10 on a silicon substrate on which a silicon oxide film is formed by sputtering nickel on the silicon substrate. A DMF solution of copolyamic acid is made from the first source material including p-phenylenediamine (PDA, Ip=7.0 eV) which is the first aromatic diamine molecule and s-BPDA (Ea=2.2 eV) which is the first aromatic tetracarboxylic dianhydride molecule and a second source material including PerDA (Ea=3.0 eV) which is the second aromatic tetracarboxylic dianhydride molecule. In the example, the second aromatic diamine molecule is PDA, which is the same as the first aromatic diamine molecule. The mole ratio of s-BPDA and PerDA is 10:1. A copolyamic acid film is formed by coating the DMF solution onto the silicon substrate by spin coating and baking at 100° C. The copolyamic acid film is heated at 350° C. Thereby, the storage layer 15 is formed on the first conductive unit 10. The storage layer 15 includes the polyimide film 16 having a thickness of 10 nm to 15 nm and the micro particles 17 including a second polyimide. The nonvolatile memory device 110 of the second example is made by forming the second conductive unit 20 by vapor-depositing gold on the storage layer 15.

In the nonvolatile memory device 110 of the second example, the first conductive unit 10 is grounded; and a voltage is applied to the second conductive unit 20. When a positive voltage is applied to the second conductive unit 20, the state is switched to the low resistance state (SET) at about 4 V (forming). Then, when a negative voltage is applied to the second conductive unit 20, the state is switched to the high resistance state at about −2 V. When the positive voltage is applied again to the second conductive unit 20, the state is switched to the low resistance state at about 3 V; and thereafter, the SET-RESET is repeated. In the state in which a voltage is not applied after being switched to the high resistance state, the high resistance state is substantially retained even after being left for about one week. In the state in which a voltage is not applied after being switched to the low resistance state, the low resistance state is substantially retained even after being left for about one week. Thus, in the nonvolatile memory device 110 of the second example, stable memory characteristics are obtained.

### Third Example

A nickel film having a thickness of 80 nm is formed as the first conductive unit 10 on a silicon substrate on which a silicon oxide film is formed by sputtering nickel on the silicon substrate. An acetonitrile solution of polyamic acid is made from the first source material including at least p-phenylenediamine (PDA, Ip=7.0 eV) which is the first aromatic diamine molecule and s-BPDA (Ea=2.2 eV) which is the first aromatic tetracarboxylic dianhydride molecule. 2,5-dimethyl-TCNQ (Ea=2.7 eV) which is an acceptor first organic molecule is dissolved in the acetonitrile solution. The mole ratio of s-BPDA and 2,5-dimethyl-TCNQ is 20:1. A polyamic acid film is formed by coating the acetonitrile solution that dissolved the first organic molecule by spin coating onto the silicon substrate and baking at 100° C. The polyamic acid film is heated at 350° C. Thereby, the storage layer 15 is formed on the first conductive unit 10. The storage layer 15 includes the polyimide film 16 having a thickness of 10 nm to 15 nm and the micro particles 17 including the first organic molecule. The nonvolatile memory device 110 of the third example is made by forming the second conductive unit 20 by vapor-depositing gold on the storage layer 15.

In the nonvolatile memory device 110 of the third example, the first conductive unit 10 is grounded; and a voltage is applied to the second conductive unit 20. When a positive voltage is applied to the second conductive unit 20, the state is switched to the low resistance state (SET) at about 4 V (forming). Then, when a negative voltage is applied to the second conductive unit 20, the state is switched to the high resistance state at about −2 V. When the positive voltage is applied again to the second conductive unit 20, the state is switched to the low resistance state at about 3 V; and thereafter, the SET-RESET is repeated. In the state in which a voltage is not applied after being switched to the high resistance state, the high resistance state is substantially retained even after being left for about one week. In the state in which a voltage is not applied after being switched to the low resistance state, the low resistance state is substantially retained even after being left for about one week. Thus, in the nonvolatile memory device 110 of the third example, stable memory characteristics are obtained.

### Fourth Example

A nickel film having a thickness of 80 nm is formed as the first conductive unit 10 on a silicon substrate on which a silicon oxide film is formed by sputtering nickel on the silicon substrate. An acetonitrile solution of polyamic acid is made from the first source material including at least p-phenylenediamine (PDA, Ip=7.0 eV) which is the first aromatic diamine molecule and s-BPDA (Ea=2.2 eV) which is the first aromatic tetracarboxylic dianhydride molecule. Iron trichloride which is an acceptor inorganic compound is dissolved in the acetonitrile solution. The mole ratio of s-BPDA and iron trichloride is 20:1. A polyamic acid film is formed by coating the acetonitrile solution that dissolves the inorganic compound onto the silicon substrate by spin coating and baking at 100° C. The polyamic acid film is heated at 350° C. Thereby, the storage layer 15 is formed on the first conductive unit 10. The storage layer 15 includes the polyimide film 16 having a thickness of 10 nm to 15 nm and the micro particles 17 including an inorganic compound. The nonvolatile memory device 110 of the fourth example is made by forming the second conductive unit 20 by vapor-depositing gold on the storage layer 15.

In the nonvolatile memory device 110 of the fourth example, the first conductive unit 10 is grounded; and a voltage is applied to the second conductive unit 20. When a positive voltage is applied to the second conductive unit 20, the state is switched to the low resistance state (SET) at about 4 V (forming). Then, when a negative voltage is applied to the second conductive unit 20, the state is switched to the high resistance state at about −2 V. When the positive voltage is applied again to the second conductive unit 20, the state is switched to the low resistance state at about 3 V; and thereafter, the SET-RESET is repeated. In the state in which a voltage is not applied after being switched to the high resistance state, the high resistance state is substantially retained even after being left for about one week. In the state in which a voltage is not applied after being switched to the low resistance state, the low resistance state is substantially retained even after being left for about one week. Thus, in the nonvolatile memory device 110 of the fourth example, stable memory characteristics are obtained.

### Fifth Example

The first conductive unit 10 that includes a titanium film having a thickness of 10 nm and a platinum film having a thickness of 80 nm is formed on a silicon substrate on which a silicon oxide film is formed by sputtering titanium and platinum in order on the silicon substrate. A DMF solution of copolyamic acid is made from the first source material including p-phenylenediamine (PDA, Ip=7.0 eV) which is the first aromatic diamine molecule and s-BPDA (Ea=2.2 eV) which is the first aromatic tetracarboxylic dianhydride molecule and a third source material including 2,3,5,6-tetramethyl-p-phenylenediamine (TMPDA, Ip=6.6 eV) which is the third aromatic diamine molecule. In the example, the third aromatic tetracarboxylic dianhydride molecule is s-BPDA which is the same as the first aromatic tetracarboxylic dianhydride molecule. The mole ratio of PDA and TMPDA is 10:1. A copolyamic acid film is formed by coating the DMF solution onto the silicon substrate by spin coating and baking at 100° C. The copolyamic acid film is heated at 350° C. Thereby, the storage layer 15 is formed on the first conductive unit 10. The storage layer 15 includes the polyimide film 16 having a thickness of 10 nm to 15 nm and the micro particles 17 including a third polyimide copolymerized with the polyimide film 16. The nonvolatile memory device 110 of the fifth example is made by forming the second conductive unit 20 by vapor-depositing copper on the storage layer 15.

In the nonvolatile memory device 110 of the fifth example, the first conductive unit 10 is grounded; and a voltage is applied to the second conductive unit 20. When a negative voltage is applied to the second conductive unit 20, the state is switched to the low resistance state (SET) at about −5 V (forming). Then, when a positive voltage is applied to the second conductive unit 20, the state is switched to the high resistance state at about 2 V. When the negative voltage is applied again to the second conductive unit 20, the state is switched to the low resistance state at about −3 V; and thereafter, the SET-RESET is repeated. In the state in which a voltage is not applied after being switched to the high resistance state, the high resistance state is substantially retained even after being left for about one week. In the state in which a voltage is not applied after being switched to the low resistance state, the low resistance state is substantially retained even after being left for about one week. Thus, in the nonvolatile memory device 110 of the fifth example, stable memory characteristics are obtained.

### Sixth Example

The first conductive unit 10 including a titanium film having a thickness of 10 nm and a platinum film having a thickness of 80 nm is formed on a silicon substrate on which a silicon oxide film is formed by sputtering titanium and platinum in order on the silicon substrate. A DMF solution of polyamic acid is made from the first source material including at least p-phenylenediamine (PDA, Ip=7.0 eV) which is the first aromatic diamine molecule and s-BPDA (Ea=2.2 eV) which is the first aromatic tetracarboxylic dianhydride molecule. N,N,N′,N′-tetramethyl-p-phenylenediamine (Ip=6.2 eV) which is a donor second organic molecule is dissolved in the DMF solution. The mole ratio of PDA and N,N,N′,N′-tetramethyl-p-phenylenediamine is 10:1. A polyamic acid film is formed by coating the DMF solution that dissolved the second organic molecule onto the silicon substrate by spin coating and baking at 100° C. The polyamic acid film is heated at 350° C. Thereby, the storage layer 15 is formed on the first conductive unit 10. The storage layer 15 includes the polyimide film 16 having a thickness of 10 nm to 15 nm and the micro particles 17 including the second organic molecule. The nonvolatile memory device 110 of the sixth example is made by forming the second conductive unit 20 by vapor-depositing copper on the storage layer 15.

In the nonvolatile memory device 110 of the sixth example, the first conductive unit 10 is grounded; and a voltage is applied to the second conductive unit 20. When a negative voltage is applied to the second conductive unit 20, the state is switched to the low resistance state (SET) at about −4.5 V (forming). Then, when a positive voltage is applied to the second conductive unit 20, the state is switched to the high resistance state at about 2.5 V. When the negative voltage is applied again to the second conductive unit 20, the state is switched to the low resistance state at about −3 V; and thereafter, the SET-RESET is repeated. In the state in which a voltage is not applied after being switched to the high resistance state, the high resistance state is substantially retained even after being left for about one week. In the state in which a voltage is not applied after being switched to the low resistance state, the low resistance state is substantially retained even after being left for about one week. Thus, in the nonvolatile memory device 110 of the sixth example, stable memory characteristics are obtained.

### First Comparative Example

When making a nonvolatile memory device of a first comparative example, the process of immersing the polyamic acid film in the silver-containing aqueous solution is omitted from the method for making the nonvolatile memory device 110 of the first example. In other words, in the nonvolatile memory device of the first comparative example, the storage layer 15 does not include the micro particles 17. In the nonvolatile memory device of the first comparative example, the switching (the transition between the low resistance state and the high resistance state) occurs at a large voltage when the first conductive unit 10 is grounded and a voltage is applied to the second conductive unit 20. However, in the nonvolatile memory device of the first comparative example, the switching is no longer observed after several repetitions.

### Second Comparative Example

The method for making a nonvolatile memory device of a second comparative example is the same as the method for making the nonvolatile memory device 110 of the fifth example except for the process of making the DMF solution. When making the DMF solution in the nonvolatile memory device of the second comparative example, the DMF solution is made using only the first source material without using the third source material. In other words, in the nonvolatile memory device of the second comparative example, the storage layer 15 does not include the micro particles 17. In the nonvolatile memory device of the second comparative example, switching is not observed even when the first conductive unit 10 is grounded and a voltage is applied to the second conductive unit 20.

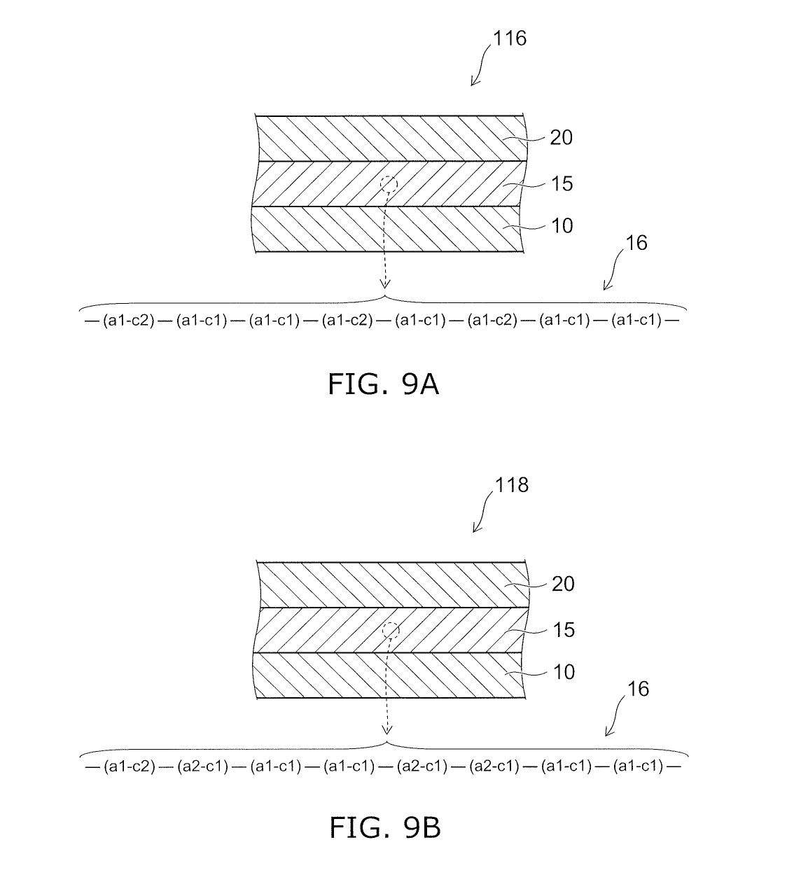

FIG. 9A and FIG. 9B are schematic cross-sectional views showing other nonvolatile memory devices according to the first embodiment.

In the storage layer 15 of a nonvolatile memory device 116 as shown in FIG. 9A, the polyimide film 16 has a first portion including a first diamine portional and a first acid anhydride portion c1, and a second portion including the first diamine portional and a second acid anhydride portion c2. In the first portion, the first diamine portion a1 is polymerized with the first acid anhydride portion c1. The first diamine portional originates in the first aromatic diamine molecule. The first acid anhydride portion c1 originates in the first aromatic tetracarboxylic dianhydride molecule. In the second portion, the first diamine portion a1 is polymerized with the second acid anhydride portion c2. The second acid anhydride portion c2 originates in the second aromatic tetracarboxylic dianhydride molecule. The first portion is copolymerized with the second portion. In other words, in the nonvolatile memory device 116, the first polyimide and the second polyimide of the nonvolatile memory device 110 are copolymerized. The first portion includes a polyimide which is made by polymerizing the first aromatic diamine molecule and the first aromatic tetracarboxylic anhydride molecule. The second portion includes a polyimide which is made by polymerizing the first aromatic diamine molecule and the second aromatic tetracarboxylic anhydride molecule. In the example, the polyimide film 16 is a copolymer. The number of the second acid anhydride portions c2 included in the polyimide film 16 is not less than 10⁻⁴ per first acid anhydride portion c1 and not more than 1 per first acid anhydride portion c1, and more favorably not less than 10⁻³ per first acid anhydride portion c1 and not more than 0.5 per first acid anhydride portion c1. The polyimide film 16 is, for example, a random copolymer. The polyimide film 16 may be, for example, a block copolymer in which the block size of the second portion is smaller than the block size of the first portion.

The polyimide film 16 is made using, for example, a source material including at least the first aromatic diamine molecule, the first aromatic tetracarboxylic anhydride molecule, and the second aromatic tetracarboxylic anhydride molecule. The second aromatic tetracarboxylic anhydride molecule is different from the first aromatic tetracarboxylic anhydride molecule. The first portion including the first diamine portion a1 and the first acid anhydride portion c1 is made by polymerizing the first aromatic diamine molecule and the first aromatic tetracarboxylic anhydride molecule. The second portion including the first diamine portional and the second acid anhydride portion c2 is made by polymerizing the first aromatic diamine molecule and the second aromatic tetracarboxylic anhydride molecule.

When making the nonvolatile memory device 116, for example, the second aromatic tetracarboxylic dianhydride molecule is mixed at the appropriate mole ratio when adjusting the solution of polyamic acid which is the precursor; and the adjusted copolyamic acid solution is coated onto the substrate. The coating method and solvent may be the same coating method and solvent as those of the first polyimide.

In the copolymer polyimide film 16, the multiple second portions can be dispersed more uniformly in the multiple first portions. Accordingly, in the nonvolatile memory device 116 using the copolymer polyimide film 16 as well, the uniformity of the memory characteristics can be increased; and the bit density can be increased.

Because the polyimide film 16 includes a copolymer, it is possible for the dispersion of the second portion in the polyimide film 16 to be particularly stable and homogeneous. In other words, in the case where the copolymer is formed, the polymer of the second portion does not move unexpectedly into the film; and the homogeneity of the trap levels also is guaranteed.

In the storage layer 15 of a nonvolatile memory device 118 as shown in FIG. 9B, the polyimide film 16 has a first portion including the first diamine portional and the first acid anhydride portion c1, and a third portion including a second diamine portion a2 and the first acid anhydride portion c1. In the third portion, the second diamine portion a2 is polymerized with the first acid anhydride portion c1. The second diamine portion a2 originates in the second aromatic diamine molecule. The third portion includes a polyimide which is made by polymerizing the second aromatic diamine molecule and the first aromatic tetracarboxylic anhydride molecule. The first portion is copolymerized with the third portion. In other words, in the nonvolatile memory device 118, the first polyimide and the third polyimide of the nonvolatile memory device 110 are copolymerized. The number of the second diamine portions a2 included in the polyimide film 16 is not less than 10⁻⁴ per first diamine portional and not more than 1 per first diamine portional. The polyimide film 16 is, for example, a random copolymer.

The polyimide film 16 is made using, for example, a source material including at least the first aromatic diamine molecule, the first aromatic tetracarboxylic anhydride molecule, and the second aromatic diamine molecule. The second aromatic diamine molecule is different from the first aromatic diamine molecule. The second aromatic diamine molecule includes the same type of molecule as the first aromatic diamine molecule.

When making the nonvolatile memory device 118, for example, the second aromatic diamine molecule is mixed at the appropriate mole ratio when adjusting the solution of polyamic acid which is the precursor; and the copolyamic acid solution is coated onto the substrate. The coating method and solvent may be the same coating method and solvent as those of the first polyimide.

In the nonvolatile memory device 118, similarly to the nonvolatile memory device 116, the uniformity of the memory characteristics can be increased; and the bit density can be increased. Because the polyimide film 16 includes a copolymer, it is possible for the dispersion of the third portion in the polyimide film 16 to be particularly homogeneous. In other words, in the case where the copolymer is formed, the polymer of the third portion does not move unexpectedly into the film; and the homogeneity of the trap levels also is guaranteed.

The polyimide film 16 may include the first portion, the second portion, and the third portion. In such a case, it is sufficient to make the polyimide film 16 using a source material including at least the first aromatic diamine molecule, the first aromatic tetracarboxylic anhydride molecule, the second aromatic tetracarboxylic dianhydride molecule, and the second aromatic diamine molecule.

### Second Embodiment

The nonvolatile memory device according to the embodiment is a cross-point nonvolatile memory device.

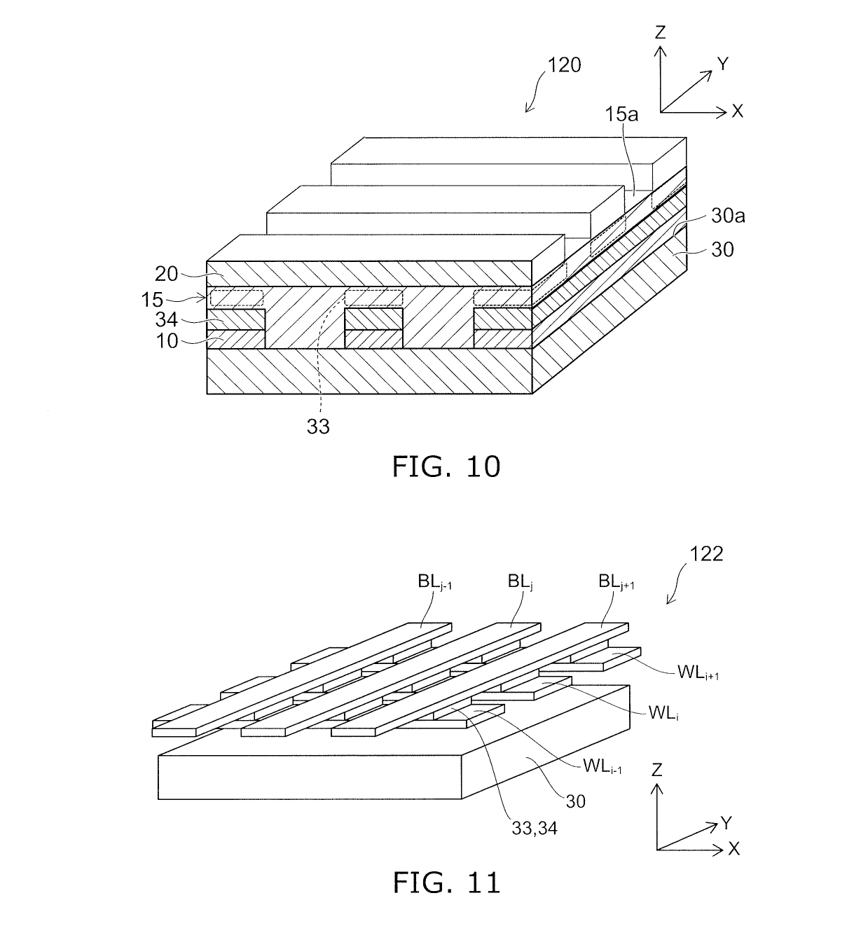

FIG. 10 is a schematic perspective view showing the nonvolatile memory device according to the second embodiment.

As shown in FIG. 10, the nonvolatile memory device 120 according to the embodiment includes a substrate 30. The substrate 30 may include, for example, a silicon substrate, a semiconductor substrate, a substrate including an inorganic substance, a substrate including a polymer, etc. The semiconductor substrate may include, for example, a silicon-on-insulator (SOI) substrate, etc. The substrate including the inorganic substance may include, for example, glass, etc.

The multiple first conductive units 10 and the multiple second conductive units 20 are provided in the nonvolatile memory device 120. Each of the multiple first conductive units 10 extends in the Y-axis direction. The multiple first conductive units 10 are arranged with a prescribed spacing in the X-axis direction. Each of the multiple second conductive units 20 extends in the X-axis direction. The multiple second conductive units 20 are arranged with a prescribed spacing in the Y-axis direction. In the example, the extension direction of the first conductive unit 10 is orthogonal to the extension direction of the second conductive unit 20. It is sufficient for the extension direction of the first conductive unit 10 to cross (be non-parallel to) the extension direction of the second conductive unit 20.

In other words, each of the multiple second conductive units 20 extends in a first direction (the X-axis direction) parallel to a major surface 30a; and the multiple second conductive units 20 are arranged in a direction (the Y-axis direction) that is parallel to the major surface 30a and crosses the first direction. Each of the multiple first conductive units 10 is provided between the major surface 30a and the multiple second conductive units 20 to extend in a second direction (the Y-axis direction) that is parallel to the major surface 30a and crosses the first direction; the multiple first conductive units 10 are arranged in a direction (the X-axis direction) that is parallel to the major surface 30a and crosses the second direction; and each of the multiple first conductive units 10 crosses each of the multiple second conductive units 20 when projected onto a plane (the X-Y plane) parallel to the major surface 30a.

The storage layer 15 is provided in each space between the multiple first conductive units 10 and the multiple second conductive units 20. In the example, the storage layer 15 also is provided between the substrate 30 and the multiple second conductive units 20. For example, the storage layer 15 is provided on the entirety of the substrate 30 and the multiple first conductive units 10. The storage layer 15 extends through each space between the multiple first conductive units 10 and the multiple second conductive units 20. The storage layer 15 has an upper surface 15a that is parallel to the major surface 30a of the substrate 30. The multiple second conductive units 20 are provided on the upper surface 15a. The thickness (the length along the Z-axis direction) of the storage layer 15 between the second conductive units 20 and the first conductive units 10 is thinner than the thickness of the storage layer 15 between the substrate 30 and the second conductive units 20.

The portion of the storage layer 15 between the first conductive unit 10 and the second conductive unit 20 acts as one memory cell 33. The portion of the storage layer 15 between the substrate 30 and the second conductive unit 20 acts as, for example, an inter-layer insulating film. The thickness of the memory cell 33 is, for example, not less than 5 nm and not more than 80 nm. The dielectric constant of the polyimide film 16 included in the storage layer 15 is lower than the dielectric constant of silicon oxide which is mainly used as inter-layer insulating films. Therefore, in the nonvolatile memory device 120, the parasitic capacitance that occurs between two mutually-adjacent first conductive units 10 can be reduced.

In the example, the multiple first conductive units 10 are, for example, word lines; and the multiple second conductive units 20 are, for example, bit lines. The first conductive units 10 may be the bit lines; and the second conductive units 20 may be the word lines. The multiple word lines and the multiple bit lines may be provided separately. In such a case, for example, it is sufficient to provide the first conductive units 10 and the second conductive units 20 only at the portions (the portions corresponding to the memory cells 33) where the word lines and the bit lines cross. The storage layer 15 may be provided only at the portions between the first conductive unit 10 and the second conductive unit 20. In other words, the multiple storage layers 15 may be provided respectively in each space between the multiple first conductive units 10 and the multiple second conductive units 20.

The nonvolatile memory device 120 further includes a rectifying element 34. The rectifying element 34 is, for example, a diode. The rectifying element 34 is multiply provided. The multiple rectifying elements 34 are provided respectively in each space between the storage layer 15 and the multiple first conductive units 10. The rectifying element 34 may be formed by, for example, causing conductors having different work functions to contact each other. The first conductive unit 10 also may function as the rectifying element 34. The rectifying element 34 is configured such that the forward direction is the orientation of the current flowing between the first conductive unit 10 and the storage layer 15. Thereby, the rectifying elements 34 suppress sneak current when programming/reading. The rectifying elements 34 may be provided between the storage layer 15 and the second conductive units 20.

In the nonvolatile memory device 120, sufficient switching characteristics can be obtained without degradation of the characteristics of the memory cell 33 even in the case where normal semiconductor processes such as vapor deposition processes, photolithography processes, dry etching, etc., are performed.

FIG. 11 is a schematic perspective view showing another nonvolatile memory device according to the second embodiment.

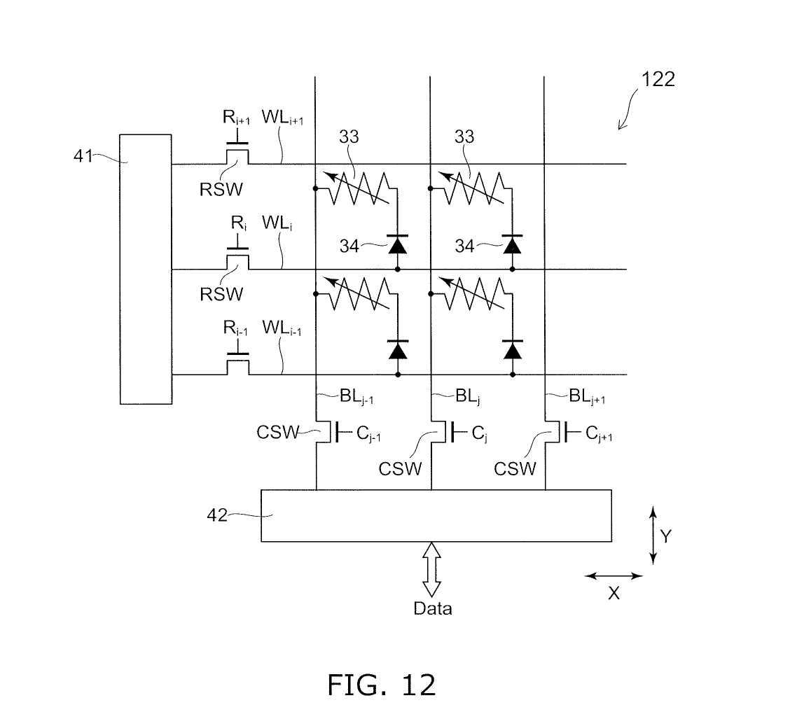

FIG. 12 is a schematic view showing the nonvolatile memory device according to the second embodiment.

In the nonvolatile memory device 122 according to the embodiment as shown in FIG. 11, first interconnects (word lines WLᵢ₋₁, WLᵢ, and WLᵢ₊₁) are provided in line configurations on the major surface of the substrate 30 to extend in the X-axis direction. Second interconnects (bit lines BLⱼ₋₁, BLⱼ, and BLⱼ₊₁) are provided in line configurations that extend in the Y-axis direction. The second interconnects (the bit lines BLⱼ₋₁, BLⱼ, and BLⱼ₊₁) oppose the first interconnects (the word lines WLᵢ₋₁, WLᵢ, and WLᵢ₊₁).

Although the extension direction of the first interconnects is orthogonal to the extension direction of the second interconnects in the description recited above, it is sufficient for the extension direction of the first interconnects to cross (be non-parallel to) the extension direction of the second interconnects.

The index i and the index j recited above are arbitrary. In other words, the number of the first interconnects and the number of the second interconnects are arbitrary.

In this specific example, the first interconnects are the word lines; and the second interconnects are the bit lines. However, the first interconnects may be the bit lines; and the second interconnects may be the word lines. In the description hereinbelow, the first interconnects are the word lines; and the second interconnects are the bit lines.

As shown in FIG. 11 and FIG. 12, the memory cells 33 are provided between the first interconnects and the second interconnects.

As shown in FIG. 12, for example, one end of each of the word lines WLᵢ₋₁, WLᵢ, and WLᵢ₊₁ is connected to a word line driver 41, which has a decoder function, via MOS transistors RSW which are selection switches. One end of each of the bit lines BLⱼ₋₁, BLⱼ, and BLⱼ₊₁ is connected to a bit line driver 42, which has a decoder function and a read-out function, via MOS transistors CSW which are selection switches.

Selection signals Rᵢ₋₁, Rᵢ, and Rᵢ₊₁ for selecting the word lines (the rows) are input to the gates of the MOS transistors RSW; and selection signals Cᵢ₋₁, Cᵢ, and Cᵢ₊₁ for selecting the bit lines (the columns) are input to the gates of the MOS transistors CSW.

The memory cells 33 are disposed at the intersections where the word lines WLᵢ₋₁, WLᵢ, and WLᵢ₊₁ and the bit lines BLⱼ₋₁, BLⱼ, and BLⱼ₊₁ oppose each other. The rectifying elements 34 may be added to the memory cells 33 to suppress the sneak current when programming/reading.

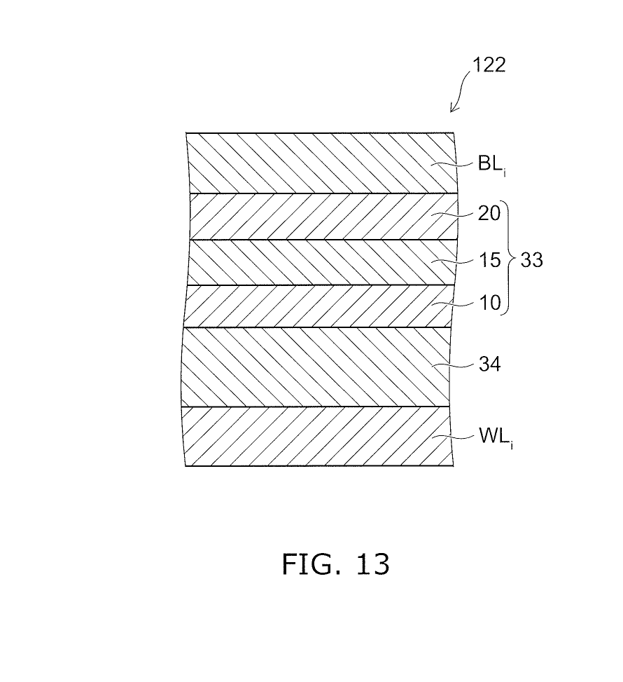

FIG. 13 is a schematic cross-sectional view showing a portion of the nonvolatile memory device according to the second embodiment.

As shown in FIG. 13, the memory cell 33 and the rectifying element 34 are provided between the word line WLᵢ and the bit line BLⱼ. The vertical disposition of the word line WLᵢ and the bit line BLⱼ is arbitrary. The order of the disposition of the memory cell 33 and the rectifying element 34 between the word line WLᵢ and the bit line BLⱼ is arbitrary.

As shown in FIG. 13, the memory cell 33 includes the first conductive unit 10, the second conductive unit 20, and the storage layer 15 provided between the first conductive unit 10 and the second conductive unit 20. The first conductive unit 10, the second conductive unit 20, and the storage layer 15 may be those described in regard to the first embodiment.

For example, at least one selected from the word line WLᵢ, the rectifying element 34, and the bit line BLⱼ that is adjacent to the memory cell 33 may be used as at least one selected from the first conductive unit 10 and the second conductive unit 20.

In the nonvolatile memory device 122 as well, because the polyimide film 16 or the copolymer polyimide film 16 including the micro particles 17 is used as the storage layer 15, the uniformity of the memory characteristics can be increased; and the bit density can be increased.

According to the embodiments, a nonvolatile memory device having high uniformity of memory characteristics and a high bit density is provided.

In the specification of the application, “perpendicular” and “parallel” refer to not only strictly perpendicular and strictly parallel but also include, for example, the fluctuation due to manufacturing processes, etc. It is sufficient to be substantially perpendicular and substantially parallel.

Hereinabove, embodiments of the invention are described with reference to specific examples. However, the embodiments of the invention are not limited to these specific examples. For example, one skilled in the art may similarly practice the invention by appropriately selecting specific configurations of components included in the nonvolatile memory device such as the first conductive unit, the second conductive unit, the storage layer, the polyimide film, the micro particles, the oxide film, etc., from known art; and such practice is included in the scope of the invention to the extent that similar effects are obtained.

Further, any two or more components of the specific examples may be combined within the extent of technical feasibility and are included in the scope of the invention to the extent that the purport of the invention is included.

Moreover, all nonvolatile memory devices practicable by an appropriate design modification by one skilled in the art based on the nonvolatile memory devices described above as embodiments of the invention also are within the scope of the invention to the extent that the spirit of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A nonvolatile memory device, comprising:
a first conductive unit;
a second conductive unit; and
a storage layer provided between the first conductive unit and the second conductive unit, the storage layer being reversibly transitionable between a first state and a second state by at least one selected from a voltage applied via the first conductive unit and the second conductive unit and a current supplied via the first conductive unit and the second conductive unit, the second state having a higher resistance than the first state,
the storage layer including a polyimide film and a plurality of micro particles dispersed in the polyimide film,
the polyimide film including a first polyimide made using a first source material including at least a first aromatic diamine molecule and a first aromatic tetracarboxylic dianhydride molecule,
the micro particles including at least one selected from a metal atom, a metal ion, a second polyimide, a third polyimide, a first organic molecule, a second organic molecule, and an inorganic compound,
the second polyimide being made using a second source material including at least a second aromatic diamine molecule and a second aromatic tetracarboxylic dianhydride molecule different from the first aromatic tetracarboxylic dianhydride molecule, an electron affinity of the second polyimide being greater than an electron affinity of the first polyimide,
the third polyimide being made using a third source material including at least a third aromatic tetracarboxylic dianhydride molecule and a third aromatic diamine molecule different from the first aromatic diamine molecule, an ionization potential of the third polyimide being less than an ionization potential of the first polyimide,
the first organic molecule being an acceptor, a molecular size of the first organic molecule being less than 1 nm, an electron affinity of the first organic molecule being greater than the electron affinity of the first polyimide,
the second organic molecule being a donor, a molecular size of the second organic molecule being less than 1 nm, an ionization potential of the second organic molecule being less than the ionization potential of the first polyimide,
the inorganic compound being an acceptor, a compound size of the inorganic compound being less than 1 nm.

2. The device according to claim 1, wherein
the number of the metal atoms is not less than 10⁻⁴ per monomer unit of the first polyimide and not more than 1 per monomer unit of the first polyimide, and
the number of the metal ions is not less than 10⁻⁴ per monomer unit of the first polyimide and not more than 1 per monomer unit of the first polyimide.

3. The device according to claim 1, wherein
the metal atom includes at least one selected from the group consisting of Sc, Ti, V, Cr, Mn, Fe, Co, Ni, Cu, Zn, Y, Zr, Nb, Mo, Ru, Rh, Pd, Ag, Cd, Hf, Ta, W, Re, Os, Ir, Pt, Au, Bi, Li, Na, K, Rb, Cs, Be, Mg, Ca, Sr, Ba, and lanthanoid, and
the metal ion includes at least one ion selected from the group consisting of Sc, Ti, V, Cr, Mn, Fe, Co, Ni, Cu, Zn, Y, Zr, Nb, Mo, Ru, Rh, Pd, Ag, Cd, Hf, Ta, W, Re, Os, Ir, Pt, Au, Bi, Li, Na, K, Rb, Cs, Be, Mg, Ca, Sr, Ba, and lanthanoid.

4. The device according to claim 1, wherein a partial charge transfer occurs between the metal atom and a section of the first polyimide originating at the first aromatic tetracarboxylic dianhydride molecule.

5. The device according to claim 1, wherein
the absolute value of the difference between the electron affinity of the first polyimide and the electron affinity of the second polyimide is not less than 0.5 eV and not more than 3.0 eV,
the absolute value of the difference between the electron affinity of the first polyimide and the electron affinity of the first organic molecule is not less than 0.5 eV and not more than 3.0 eV,
the absolute value of the difference between the ionization potential of the first polyimide and the ionization potential of the third polyimide is not less than 0.5 eV and not more than 3.0 eV, and
the absolute value of the difference between the ionization potential of the first polyimide and the ionization potential of the second organic molecule is not less than 0.5 eV and not more than 3.0 eV.

6. The device according to claim 1, wherein
the number of monomers of the second polyimide is not less than 10⁻⁴ per monomer unit of the first polyimide and not more than 1 per monomer unit of the first polyimide,
the number of monomers of the third polyimide is not less than 10⁻⁴ per monomer unit of the first polyimide and not more than 1 per monomer unit of the first polyimide,
the number of the first organic molecules is not less than 10⁻⁴ per monomer unit of the first polyimide and not more than 1 per monomer unit of the first polyimide,
the number of the second organic molecules is not less than 10⁻⁴ per monomer unit of the first polyimide and not more than 1 per monomer unit of the first polyimide, and
the number of particles of the inorganic compound is not less than 10⁻⁴ per monomer unit of the first polyimide and not more than 1 per monomer unit of the first polyimide.

7. The device according to claim 1, wherein the first organic molecule includes at least one selected from the group consisting of quinone, quinone derivative, TCNQ, TCNQ derivative, DCNQI, DCNQI derivative, fluorene, and fluorene derivative.

8. The device according to claim 1, wherein a partial charge transfer occurs between the first organic molecule and a section of the first polyimide originating at the first aromatic diamine molecule.

9. The device according to claim 1, wherein the second organic molecule includes at least one selected from the group consisting of TTF, TTF derivative, diamine, polycyclic aromatic hydrocarbon, metallocene, phthalocyanine, and porphyrin.

10. The device according to claim 1, wherein a partial charge transfer occurs between the second organic molecule and a section of the first polyimide originating at the first aromatic tetracarboxylic dianhydride molecule.

11. The device according to claim 1, wherein the inorganic compound includes at least one selected from the group consisting of:
a halogen including at least one selected from Cl₂, Br₂, I₂, ICl, ICl₃, IBr, and IF;
a Lewis acid including at least one selected from PF₅, AsF₅, SbF₅, BF₃, BCl₃, BBr₃, and SO₃;
a transition metal halide including at least one selected from FeCl₃, FeOCl, TiCl₄, ZrCl₄, HfCl₄, NbF₅, NbCl₅, TaCl₅, MoF₅, MoCl₅, WF₆, WCl₆, UF₆, ReF₆, MoF₆, OsF₆, and LnCl₃ (Ln being a lanthanoid);
a proton acid including at least one selected from HF, HCl, HNO₃, H₂SO₄, HClO₄, FSO₃H, CISO₃H, and CF₃SO₃H; and
an electrolyte anion including at least one selected from Cl⁻, Br⁻, I⁻, ClO₄⁻, PF₆⁻, AsF₆⁻, SbF₆⁻, and BF₄⁻.

12. The device according to claim 1, wherein the inorganic compound is configured to form a charge-transfer salt with a section of the first polyimide originating at the first aromatic diamine molecule.

13. The device according to claim 1, wherein
the first conductive unit includes at least one selected from the group consisting of Au, Ag, Cu, Ni, Al, Pt, Ti, W, TiN, TaN, WN, and polySi, and
the second conductive unit includes at least one selected from the group consisting of Au, Ag, Cu, Ni, Al, Pt, Ti, W, TiN, TaN, WN, and polySi.

14. The device according to claim 1, further comprising an oxide film provided between the first conductive unit and the storage layer and/or between the second conductive unit and the storage layer.

15. The device according to claim 1, further comprising an organic coupling layer provided between the first conductive unit and the storage layer and/or between the second conductive unit and the storage layer.

16. The device according to claim 1, further comprising a substrate having a major surface,
a plurality of the first conductive units and a plurality of the second conductive units being provided,
each of the second conductive units extending in a first direction parallel to the major surface, the second conductive units being arranged in a direction parallel to the major surface and crossing the first direction,
each of the first conductive units being provided between the major surface and the second conductive units to extend in a second direction parallel to the major surface and crossing the first direction, the first conductive units being arranged in a direction parallel to the major surface and crossing the second direction, each of the first conductive units crossing each of the second conductive units when projected onto a plane parallel to the major surface, and
the storage layer extending through each space between the first conductive units and the second conductive units.

17. A nonvolatile memory device, comprising:
a first conductive unit;
a second conductive unit; and
a storage layer provided between the first conductive unit and the second conductive unit, the storage layer being reversibly transitionable between a first state and a second state by at least one selected from a voltage applied via the first conductive unit and the second conductive unit and a current supplied via the first conductive unit and the second conductive unit, the second state having a higher resistance than the first state,
the storage layer including a polyimide film made using a source material including a first aromatic diamine molecule and a first aromatic tetracarboxylic dianhydride molecule, the source material further including at least one selected from a second aromatic tetracarboxylic dianhydride molecule and a second aromatic diamine molecule, the second aromatic tetracarboxylic dianhydride molecule being different from the first aromatic tetracarboxylic dianhydride molecule, the second aromatic diamine molecule being different from the first aromatic diamine molecule.

18. The device according to claim 17, wherein the polyimide film is a random copolymer.

19. The device according to claim 17, wherein
the polyimide film is made using a source material including at least the first aromatic diamine molecule, the first aromatic tetracarboxylic dianhydride molecule, and the second aromatic tetracarboxylic dianhydride molecule, and the polyimide film has a first portion and a second portion copolymerized with the first portion,
the first portion has a first diamine portion and a first acid anhydride portion polymerized with the first diamine portion, the first diamine portion originating in the first aromatic diamine molecule, the first acid anhydride portion originating in the first aromatic tetracarboxylic dianhydride molecule, and
the second portion has the first diamine portion and a second acid anhydride portion polymerized with the first diamine portion, the second acid anhydride portion originating in the second aromatic tetracarboxylic dianhydride molecule.

20. The device according to claim 17, wherein
the polyimide film is made using a source material including at least the first aromatic diamine molecule, the first aromatic tetracarboxylic dianhydride molecule, and the second aromatic diamine molecule, and the polyimide film has a first portion and a third portion copolymerized with the first portion,
the first portion has a first diamine portion and a first acid anhydride portion polymerized with the first diamine portion, the first diamine portion originating in the first aromatic diamine molecule, the first acid anhydride portion originating in the first aromatic tetracarboxylic dianhydride molecule, and
the third portion has a second diamine portion and the first acid anhydride portion polymerized with the second diamine portion, the second diamine portion originating in the second aromatic diamine molecule.
